(19) United States
(12) Patent Application Publication
(10) Pub. No.: US 2026/0013141 A1
(43) Pub. Date: Jan. 8, 2026

(54) MEMORY CELLS AND METHOD OF MANUFACTURING A MEMORY CAPACITOR

(71) Applicant: Ferroelectric Memory GmbH, Dresden (DE)

(72) Inventors: Bart Vermeulen, Dresden (DE); Tony Schenk, Dresden (DE)

(21) Appl. No.: 18/764,429

(22) Filed: Jul. 5, 2024

(51) Int. Cl. H10B 53/30

(52) U.S. Cl. CPC H10B 53/30

(57) ABSTRACT

Memory cells and a method of manufacturing a memory capacitor are disclosed, wherein a memory cell includes: a first electrode; a second electrode; and a memory element disposed between the first electrode and the second electrode, wherein the first electrode, the second electrode, and the memory element form a memory capacitor; wherein the memory element includes a spontaneously polarizable memory layer stack, the spontaneously polarizable memory layer stack including an alternating sequence of first sublayers and second sublayers, wherein each of the first sublayers substantially consists of zirconium oxide having a first oxygen concentration, and wherein each of the second sublayers substantially consists of hafnium zirconium oxide having a second oxygen concentration, wherein the first oxygen concentration is substantially greater than the second oxygen concentration.

### TECHNICAL FIELD

Various aspects relate to memory cells and a method of manufacturing a memory capacitor.

### BACKGROUND

In general, various computer memory technologies have been developed in semiconductor industry. A fundamental building block of a computer memory may be referred to as memory cell. The memory cell may be an electronic circuit that is configured to store at an information (e.g., bitwise). As an example, the memory cell may have at least two memory states representing, for example, a logic “1” and a logic “0”. In general, the information may be maintained (stored) in a memory cell until the memory state of the memory cell is modified, e.g., in a controlled manner. The information stored in the memory cell may be obtained (read out) by determining in which of the memory states the memory cell is residing in. At present, various types of memory cells may be used to store data. By way of example, a type of memory cell may include a thin film of a spontaneous-polarizable material, e.g., a ferroelectric material or a configuration of an anti-ferroelectric material, whose polarization state may be changed in a controlled fashion to store data in the memory cell, e.g., in a non-volatile manner. A memory cell or an arrangement of memory cells may be integrated, for example, on a wafer or a chip together with one or more logic circuits.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A to FIG. 1C each show various aspects of a capacitive memory structure in a schematic view;

FIG. 1D and FIG. 1E each show a memory cell arrangement according to various aspects;

FIG. 2A to FIG. 2I each show at least one spontaneously polarizable capacitor structure conformally covering a three-dimensional structure according to various aspects;

FIG. 3A to FIG. 3H each show an exemplary configuration of a spontaneously polarizable capacitor structure according to various aspects;

FIG. 4 to FIG. 7 each show a flow diagram of a method of manufacturing a memory capacitor according to various aspects; and

FIG. 8 and FIG. 9 each show exemplary configurations during forming a doped sublayer of the memory capacitor according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a memory cell, or a memory capacitor). However, it may be understood that aspects described in connection with methods may similarly apply to the devices, and vice versa.

In the semiconductor industry, the integration of non-volatile memory technologies, sensor technologies, transmitter technologies, electronic filter technologies, receiver technologies, and the like may be useful for various types of devices and applications. According to various aspects, an electronic device, e.g., a non-volatile memory may be integrated on a chip.

A capacitive memory structure (also referred to as spontaneously polarizable capacitor structure) of a memory cell may include a memory element disposed between two electrode layers (e.g., a bottom electrode layer and a top electrode layer). This capacitive memory structure may define the electronic properties of the memory cell and thus, the overall memory cell arrangement. In general, leakage in a spontaneously polarizable capacitor structure can lead to discharging of the capacitor, increased power consumption during (polarization) switching, higher stress operation and, hence, accelerated breakdown.

Various aspects relate to configurations of a spontaneously polarizable capacitor structure having a reduced (e.g., suppressed) leakage. The memory element of the spontaneously polarizable capacitor structure may include an alternating sequence of first sublayers and second sublayers with the second sublayers substantially consisting of hafnium zirconium oxide (HZO). In a first configuration, the first sublayers may substantially consist of zirconium oxide. In this case, the leakage can be reduced by engineering the oxygen concentration of the first sublayers and/or second sublayers. The oxygen content can be engineered by adjusting the parameters of an oxygen-containing pulse during atomic layer deposition and/or by doping the first sublayers and/or the second sublayers. In a second configuration, the first sublayers may substantially consist of antiferroelectric hafnium oxide. In this case, the first sublayers may be doped with a dopant which stabilizes the tetragonal crystal structure of hafnium oxide to achieve the antiferroelectric properties. Antiferroelectric hafnium oxide has a lower leakage than zirconium oxide, thereby reducing leakage of the spontaneously polarizable capacitor structure.

Further, all disclosed configurations of the spontaneously polarizable capacitor structure are compatible with (i.e., manufacturable by) atomic layer deposition (ALD). Thus, the disclosed configurations of the spontaneously polarizable capacitor structure can be used in planar structures as well as three-dimensional (3D) structures.

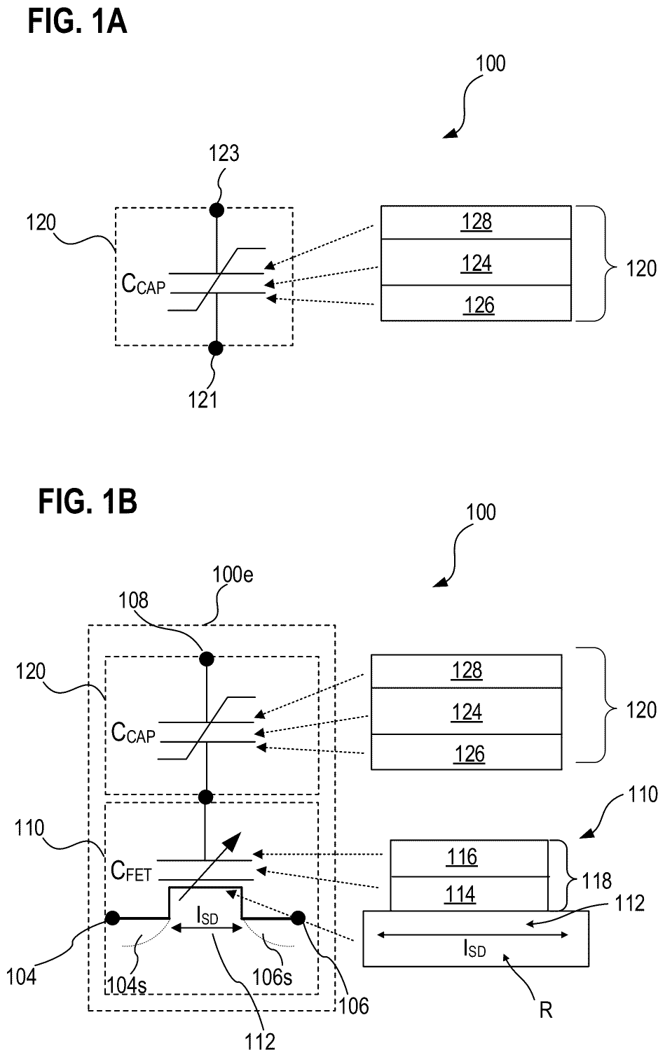

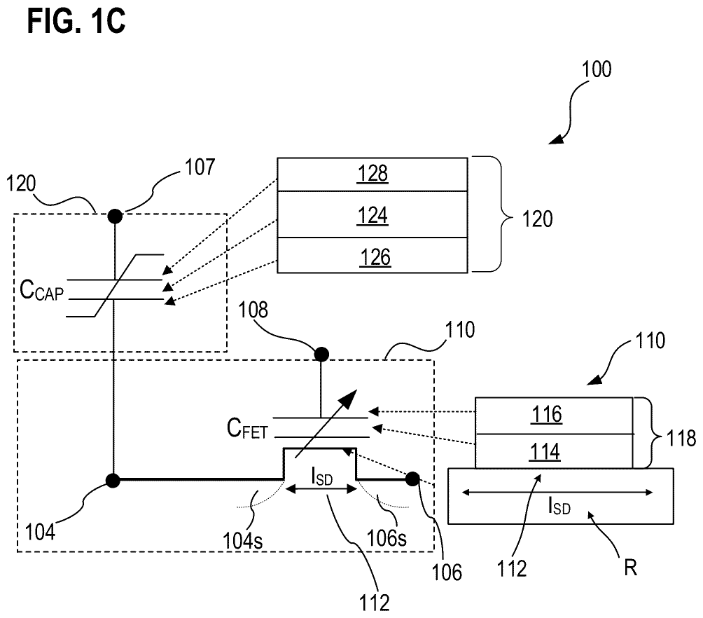

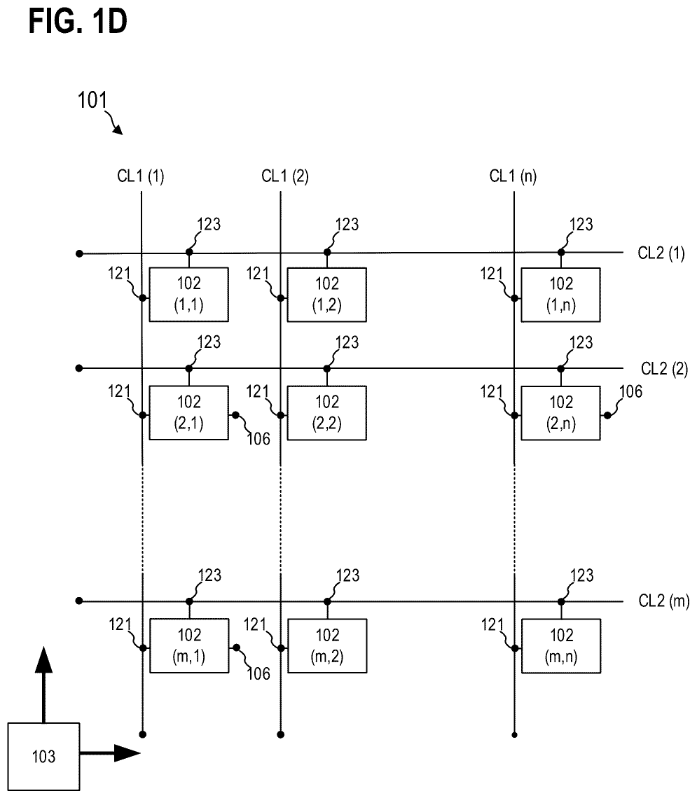

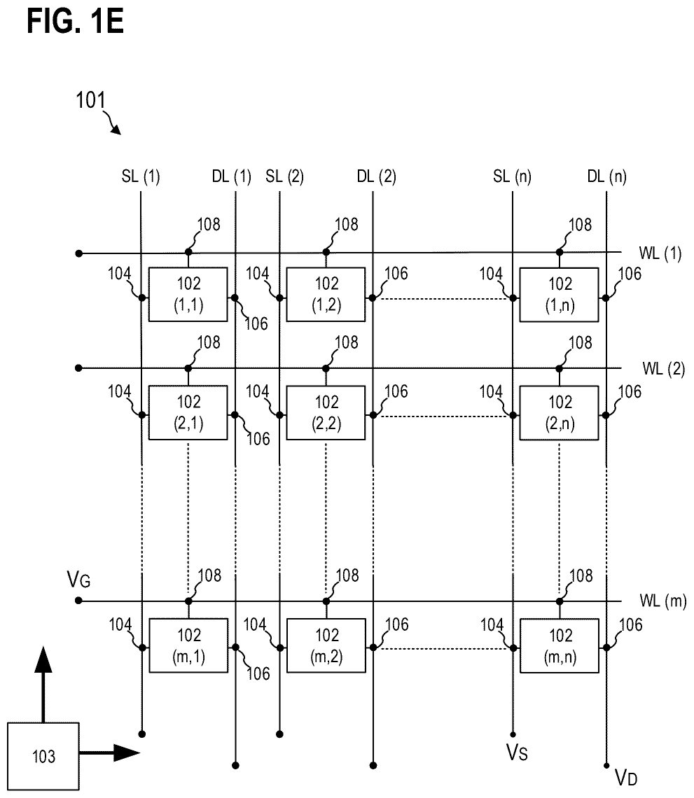

FIG. 1A shows various aspects of a memory structure 100. The memory structure 100 may include a capacitive memory structure, such as a spontaneously polarizable capacitor, SPOC, structure 120. The SPOC structure 120 (in some aspects also referred to as memory layer stack) may include at least two electrodes (e.g., two electrode layers), such as a first electrode 126 and a second electrode 128. The SPOC structure 120 may include a memory element 124. The memory element 124 may be disposed between the first electrode 126 and the second electrode 128. The memory element 124 may be disposed in direct physical contact with the first electrode 126 and in direct physical contact with the second electrode 128. The memory element 124 may include or may consist of a spontaneously polarizable material. A memory element including or consisting of a spontaneously polarizable material may also be referred to as spontaneously-polarizable memory element 124. For example, the spontaneously polarizable material may be a remanent polarizable material, such as a ferroelectric material, or a non-remanent polarizable material, such as an anti-ferroelectric material. A memory element including or consisting of a spontaneously polarizable material may be understood such that the memory element has (e.g., within the framework of the SPOC structure 120) spontaneously polarizable properties. According to various aspects, the first electrode 126, the second electrode 128, and the memory element 124 may form the SPOC structure 120. The SPOC structure 120 may, in some aspects, also be referred to as memory capacitor.

The SPOC structure 120 may be part of or may form a memory cell 102. The first electrode 126 may be coupled to a first terminal 121 and the second electrode 128 may be coupled to a second terminal 123. Thus, in this scenario, the memory cell 102 may be a two-terminal memory cell (see, for example, the memory cell arrangement 101 shown in FIG. 1D).

The spontaneously-polarizable memory element 124 may show a hysteresis in the (voltage (drop) dependent) polarization. The spontaneously-polarizable memory element 124 may show non-remanent spontaneous polarization (e.g., may show anti-ferroelectric properties), e.g., the spontaneously-polarizable memory element may have no or no substantial remanent polarization remaining in the case that no voltage drops over the spontaneously-polarizable memory element 124. In other aspects, the spontaneously-polarizable memory element 124 may show remanent spontaneous polarization (e.g., may show ferroelectric properties), e.g., the spontaneously-polarizable memory element 124 may have a remanent polarization or a substantial remanent polarization remaining in the case that no voltage drops over the spontaneously-polarizable memory element.

The terms “spontaneously polarized” or “spontaneous polarization” may be used herein, for example, with reference to the polarization capability of a material beyond dielectric polarization. A “spontaneously-polarizable” (or “spontaneous-polarizable”) material may be or may include a spontaneously-polarizable material that shows a remanence, e.g., a ferroelectric material, and/or a spontaneously-polarizable material that shows no remanence, e.g., an anti-ferroelectric material. The coercivity of the spontaneously-polarizable material may be a measure of the strength of the reverse polarizing electric field that may be required to remove a remanent polarization.

A spontaneous polarization (e.g., a remanent or non-remanent spontaneous polarization) may be evaluated via analyzing one or more hysteresis measurements (e.g., hysteresis curves), e.g., in a plot of polarization, P, versus electric field, E, in which the material is polarized into opposite directions. The polarization capability of a material (dielectric polarization, spontaneous polarization, and a remanence characteristics of the polarization) may be analyzed using capacity spectroscopy, e.g., via a static (C-V) and/or time-resolved measurement or by polarization-voltage (P-V) or positive-up-negative-down (PUND) measurements.

According to various aspects, in various types of applications, e.g., in memory technology, a remanent polarization as low as 0 μC/cm² to 3 μC/cm² may be regarded as no substantial remanent polarization. Such low values of a remanent polarization may be present in a layer or material due to undesired effects, e.g., due to a not ideal layer formation. According to various aspects, in various types of applications, e.g., in memory technology, a remanent polarization greater than 3 μC/cm² may be regarded as substantial remanent polarization. Such a substantial remanent polarization may allow for storing information as a function of a polarization state of a spontaneously polarizable layer or a spontaneously polarizable material.

In a usual capacitor structure, the amount of charge stored therein may be used to define a memory state (e.g., first amount of charge stored in the capacitor structure may define a first memory state and a second amount of charge stored in the capacitor structure may define a second memory state.

In general, a remanent polarization (also referred to as retentivity or remanence) may be present in a material layer in the case that the material layer may remain polarized upon reduction of an applied electric field (E) to zero, therefore, a certain value for the electrical polarization (P) of the material layer may be detected. Illustratively, a polarization remaining in a material when the electric field is reduced to zero may be referred to as remanent polarization. Therefore, the remanence of a material may be a measure of the residual polarization in the material in the case that an applied electric field is removed. In general, ferroelectricity and anti-ferroelectricity may be concepts to describe a spontaneous polarization of a material similar to ferromagnetism and anti-ferromagnetism used to describe remanent magnetization in magnetic materials. According to various aspects, an electric coercive field, E_{C}, (also referred to as coercive field) may be or may represent the electric field required to depolarize a remanent-polarizable layer.

According to various aspects, the spontaneously-polarizable memory element 124 may include or may consist of a remanent-polarizable material. A remanent-polarizable material may be a material that is remanently polarizable and shows a remanence of the spontaneous polarization, such as a ferroelectric material. In other aspects, remanent-polarizable material may be a material that is spontaneously polarizable and that shows no remanence, e.g., an anti-ferroelectric material under the additional conditions that measures are implemented to generate an internal electric-field within the anti-ferroelectric material. Hence, a non-remanently polarizable material, such as an anti-ferroelectric (“antiferroelectric”) material may exhibit remanent polarizable properties within certain structures. An internal electric-field within an anti-ferroelectric material may be caused (e.g., applied, generated, maintained, as examples) by various strategies: e.g., by implementing floating nodes that may be charged to voltages different from zero volts, and/or by implementing charge storage layers, and/or by using doped layers, and/or by using electrode layers that adapt electronic work-functions to generate an internal electric field, by using an encapsulation structure which introduces compressive stress or tensile stress onto the memory element 124, thereby establishing the spontaneously polarizable properties, only as examples. The spontaneously-polarizable memory element 124 including or being made of a remanent-polarizable material may be referred to herein as remanent-polarizable memory element (e.g., as remanent-polarizable layer).

According to various aspects, the memory capacitor as provided by the SPOC structure 120 may be or may include a ferroelectric capacitor (FeCAP) or an anti-ferroelectric capacitor (AFeCAP). An information may be stored by the memory capacitor via at least two remanent polarization states of the SPOC structure 120. The programming of the SPOC structure 120 (illustratively the storage of information therein) may be carried out by providing (e.g., applying) an electric field to thereby set or change the remanent polarization state of the spontaneously polarizable memory element 124. Illustratively, the spontaneous-polarizable material (e.g., a ferroelectric material, e.g., an anti-ferroelectric material) may be used to store data in non-volatile manner in integrated circuits.

It may be understood that, even though various aspects refer to a memory element including or being made of a spontaneously-polarizable material, other memory elements whose state may be altered by an electric field provided across a capacitive memory structure may be used as long as the structure of the material can be changed via application of an electric field, as described herein.

The SPOC structure 120 may have a capacitive configuration with a (first) capacitance, C_{CAP}, associated therewith (see equivalent circuit 100e in FIG. 1A with respect to the capacitive properties). The first electrode 126, the memory element 124, and the second electrode 128 may form a memory capacitor. In some aspects, the memory capacitor may be a planar layer stack; however, other shapes may be suitable as well, e.g., curved shapes, angled shapes, coaxially aligned shapes, as examples. Illustratively, the SPOC structure 120 may include planar electrodes, or, in other aspects, the SPOC structure 120 may be configured as 3D capacitor including, for example, angled or curved electrodes.

With reference to FIG. 1B, the memory structure 100 may be a field-effect transistor (FET) based capacitive memory structure (e.g., including a ferroelectric FET, FeFET). The memory structure 100 may include a field-effect transistor structure 110 and the capacitive memory structure (e.g., the SPOC structure 120). The SPOC structure 120 may be coupled to a gate structure 118 of the FET. The gate structure 118 may include a gate isolation 114 and a gate electrode 116. The gate structure 118 is illustrated exemplarily as a planar gate stack; however, it is understood that the planar configurations shown in FIG. 1A and FIG. 1B are examples, and that other field-effect transistor designs may include a gate structure 118 with a non-planar shape, for example a trench gate transistor design, a vertical field-effect transistor design, or other designs, such as a fin-FET design.

In this scenario, the memory cell 102 may be a three-terminal memory cell. Thus, the memory cell 102 may have a first terminal 104 (e.g., a source terminal), a second terminal 106 (e.g., a drain terminal), and a third terminal 108 (e.g., a gate terminal). The memory cell 102 may include a field-effect transistor structure 110. The field-effect transistor structure 110 may include a first source/drain region 104s (e.g., a source region). The first source/drain region 104s may be connected to the first terminal 104 of the memory cell 102. The field-effect transistor structure 110 may include a second source/drain region 106s (e.g., a drain region). The second source/drain region 106s may be connected to the second terminal 106 of the memory cell 102. The field-effect transistor structure 110 may include the gate structure 108g (e.g., a gate region). The gate structure 108g may be connected to the third terminal 108 of the memory cell 102.

The gate structure 118 may define a channel region 112, e.g., provided in a semiconductor portion (e.g., in a semiconductor layer, in a semiconductor die, etc.). The gate structure 118 may allow for a control of an electrical behavior (e.g., a resistance R) of the channel region 112, e.g., a current flow in the channel region 112 may be controlled (e.g., allowed, increased, prevented, decreased, etc.). In some aspects, the gate structure 118 may, for example, allow to control (e.g., allow or prevent) a source/drain current, I_{SD}, from a first source/drain region of the field-effect transistor structure 110 to a second source/drain region of the field-effect transistor structure 110 (the source/drains are provided in or adjacent to the channel but are not shown in FIG. 1B). The channel region 112 and the source/drain regions may be formed, e.g., via doping one or more semiconductor materials or by the use of intrinsically doped semiconductor materials, within a layer and/or over a layer. With respect to the operation of the field-effect transistor structure 110, a voltage may be provided at the gate electrode 116 to control the current flow, I_{SD}, in the channel region 112, the current flow, I_{SD}, in the channel region 112 being caused by voltages supplied via the source/drain regions.

According to various aspects, the semiconductor portion (illustratively, where the channel region 112 may be formed), may be made of or may include silicon. However, other semiconductor materials of various types may be used in a similar way, e.g., germanium, Group III to V (e.g., SiC), or other types, including for example carbon nanotubes, organic materials (e.g., organic polymers), etc. In various aspects, the semiconductor portion may be a wafer made of silicon (e.g., p-type doped or n-type doped). In other aspects, the semiconductor portion may be a silicon on insulator (SOI) wafer. In other aspects, the semiconductor portion may be provided by a semiconductor structure, e.g., by one or more semiconductor fins, one or more semiconductor nanosheets, one or more semiconductor nanowires, etc., disposed at a carrier.

The gate electrode 116 may include an electrically conductive material, for example, a metal, a metal alloy, a degenerate semiconductor (in other words a semiconductor material having such a high level of doping that the material acts like a metal and not anymore as a semiconductor), and/or the like. As an example, the gate electrode 116 may include or may be made of aluminum. As another example, the gate electrode 116 may include or may be made of polysilicon. According to various aspects, the gate electrode 116 may include one or more electrically conductive portions, layers, etc. The gate electrode 116 may include, for example, one or more metal layers (also referred to as a metal gate), one or more polysilicon layers (also referred to as poly-Si-gate), etc. A metal gate may include, for example, at least one work-function adaption metal layer disposed over the gate isolation 114 and an additional metal layer disposed over the work-function adaption metal layer. A poly-Si-gate may be, for example, p-type doped or n-type doped.

The gate isolation 114 may be configured to provide an electrical separation of the gate electrode 116 from the channel region 112 and further to influence the channel region 112 via an electric field generated by the gate electrode 116. The gate isolation 114 may include one or more electrically insulating layers, as an example. Some designs of the gate isolation 114 may include at least two layers including different materials, e.g., a first gate isolation layer (e.g., a first dielectric layer including a first dielectric material) and a second gate isolation layer (e.g., a second dielectric layer including a second dielectric material distinct from first dielectric material).

As illustrated by the circuit equivalent in FIG. 1B, a (second) capacitance, C_{FET}, may be associated with the field-effect transistor structure 110. Illustratively, the channel region 112, the gate isolation 114, and the gate electrode 116 may have a capacitance, C_{FET}, associated therewith, originating from the more or less conductive regions (the channel region 112 and the gate electrode 116) separated from one another by the gate isolation 114. Further illustratively, the channel region 112 may be considered as a first capacitor electrode, the gate electrode 116 as a second capacitor electrode, and the gate isolation 114 as a dielectric medium between the two capacitor electrodes. The capacitance, C_{FET}, of the field-effect transistor structure 110 may define one or more operating properties of the field-effect transistor structure 110. The configuration of the field-effect transistor structure 110 (e.g., of the gate isolation 114) may be adapted according to a desired behavior or application of the field-effect transistor structure 110 during operation (e.g., according to a desired capacitance).

In general, the capacitance, C, of a planar capacitor structure may be expressed as,

$$C = {ε}_{0} {ε}_{r} \frac{A}{d} ,$$

with ε₀ being the permittivity of the vacuum, A being the effective area of the capacitor, d being the distance of the two capacitor electrodes from one another, and εᵣ being the relative permittivity of the dielectric material disposed between two capacitor electrodes assuming that the whole gap between the two capacitor electrodes is filled with the dielectric material. It is noted that the capacitance of a non-planar capacitor structure or of a modified variant of a planar capacitor structure may be calculated based on equations known in the art.

In some aspects, the gate electrode 116 of the field-effect transistor structure 110 and the first electrode 126 of the SPOC structure 120 that is connected to the field-effect transistor structure 110 may be spatially separated from one another and electrically connected via a conductive connection, e.g., one or more metal lines. In other aspects, the gate electrode 116 of the field-effect transistor structure 110 and the first electrode 126 of the SPOC structure 120 may be in direct physical contact with one another or implemented as a single (shared) electrode. For example, an electrode layer may (as single (shared) electrode) provide both, the gate electrode 116 of the field-effect transistor structure 110 and the first electrode 126 of the SPOC structure 120.

The SPOC structure 120 may allow adapting the capacitances C_{FET}, C_{CAP} of the respective capacitors to allow an efficient programming of the memory cell. The overall gate voltage required for switching the memory cell from one memory state into another memory state (e.g., from high threshold voltage state to low threshold voltage state, as described below), may become smaller in case the voltage distribution across the field-effect transistor structure 110 and the SPOC structure 120 is adapted such that more of the applied gate voltage drops across the memory layer of the SPOC structure 120 (e.g., across the memory element 124) than across the gate isolation of the field-effect transistor structure 110. The overall write voltage (illustratively, applied via nodes to which the field-effect transistor structure 110 and the SPOC structure 120 are connected) may thus be reduced by adapting the capacitive voltage divider. The voltage distribution may be determined by voltage divider calculations for a series connection of the capacitors.

That is, in the case that the capacitance, C_{FET}, of the field-effect transistor structure 110 is adapted (e.g., by providing a suitable gate isolation) a predefined fraction of the voltage applied to the series connection may drop across the SPOC structure 120. Accordingly, the electric field generated across the gate isolation of the field-effect transistor structure 110 underneath the SPOC structure 120 could be reduced if desired. This may lead to a reduced interfacial field stress, which may lead to a reduced wear out of the interface due to, for example, charge injection. Therefore, the reduced electric field generated across the gate isolation may lead to improved endurance characteristics of the memory cell, that is, to an increased amount of possible state reversals until the memory cell may lose or change its memory properties.

By increasing the capacitance C_{FET} of the field-effect transistor structure 110 (e.g., by providing a gate isolation including a relatively thick layer of material with high dielectric constant), the depolarization field, E_{Dep}, of the spontaneously polarizable material of the memory element 124 may be reduced. The depolarization field may be expressed by the following set of equations, wherein the indices “FET” refer to the capacitor provided by the field-effect transistor structure 110 and the indices “CAP” refer to the capacitor provided by the SPOC structure 120, as described herein:

$${V}_{FET} + {V}_{CAP} = 0 ,$$

$$D = {ε}_{0} {ε}_{FET} {E}_{FET} = {ε}_{0} {ε}_{CAP} {E}_{CAP} + P ,$$

$${E}_{CAP} ≡ {E}_{Dep} = - {P ( {ε}_{0} {ε}_{CAP} ( \frac{{C}_{FET}}{{C}_{CAP}} + 1 ) )}^{- 1} .$$

The depolarization field E_{Dep} may be detrimental to data retention since, depending on its magnitude, it may depolarize the remanent-polarizable layer. However, the magnitude may be reduced by increasing the capacitance ratio C_{FET}/C_{CAP}. Accordingly, in case the capacitance C_{FET} of the field-effect transistor structure 110 is increased, the depolarization field is reduced. This in turn improves the data retention of the memory cell.

According to various aspects, a threshold voltage of a field-effect transistor structure (and in a corresponding manner the threshold voltage of a field-effect transistor based memory cell) may be defined as a constant current threshold voltage (referred to as V_{th(ci)}). In this case, the constant current threshold voltage, V_{th(ci)}, may be a determined gate source voltage, V_{GS}, at which the drain current (referred to as I_{D}) is equal to a predefined (constant) current. The predefined (constant) current may be a reference current (referred to as I_{D0}) times the ratio of gate width (W) to gate length (L). The magnitude of the reference current, I_{D0}, may be selected to be appropriate for a given technology, e.g., 0.1 μA. In some aspects, the constant current threshold voltage, V_{th(ci)}, may be determined based on the following equation:

$${V}_{t h ( c i )} = {V}_{GS} ( at {I}_{D} = {I}_{D 0} \cdot W / L ) .$$

A threshold voltage of a field-effect transistor structure (e.g., of the field-effect transistor structure 110) may be defined by the properties of the field-effect transistor structure (e.g., the materials, the doping, etc.), and it may thus be a (e.g., intrinsic) property of the field-effect transistor structure.

A memory cell including a field-effect transistor structure may include a first memory state, for example associated with a low threshold voltage state (referred to as LVT associated with the LVT memory state), and a second memory state, for example associated with a high threshold voltage state (referred to as HVT state associated with the HVT memory state). The high threshold voltage state may be, in some aspects, associated with a lower current flow during readout than the low threshold voltage state. The low threshold voltage state may be an electrically conducting state (e.g., associated with a logic memory state “1”, also referred to as a memory state or programmed state) and the high threshold voltage state may be an electrically non conducting state or at least less conducting than the low threshold voltage state (e.g., associated with a logic memory state “0”, also referred to as a memory state or erased state). However, the definition of the LVT state and the HVT state and/or the definition of a logic “0” and a logic “1” and/or the definition of “programmed state” and “erased state” may be selected arbitrarily. Illustratively, the first memory state may be associated with a first threshold voltage of the FET based memory cell, and the second memory state may be associated with a second threshold voltage of the FET based memory cell. However, the definition of the memory states and/or the definition of a logic “0” and a logic “1” may be selected arbitrarily.

According to various aspects, the residual polarization of the memory element 124 (e.g., the polarization of the spontaneously-polarizable material of the memory element 124) may define the memory state a memory cell is residing in. According to various aspects, a memory cell may reside in a first memory state in the case that the memory element is in a first polarization state, and the memory cell may reside in a second memory state in the case that the memory element is in a second polarization state (e.g., opposite to the first polarization state). As an example, the polarization state of the memory element may determine the amount of charge stored in the SPOC structure 120. The amount of charge stored in the SPOC structure 120 may be used to define a memory state of the memory cell. The threshold voltage of a field-effect transistor structure may be a function of the polarization state of the memory element 124, e.g., may be a function of the amount and/or polarity of charge stored in the SPOC structure 120. A first threshold voltage, e.g., a low threshold voltage V_{L-th}, may be associated with the first polarization state (e.g., with the first amount and/or polarity of stored charge), and a second threshold voltage, e.g., a high threshold voltage V_{H-th}, may be associated with the second polarization state (e.g., with the second amount and/or polarity of stored charge). A current flow from nodes to which the field-effect transistor structure and the SPOC structure 120 are coupled may be used to determine the memory state in which the memory cell is residing in.

According to various aspects, writing a memory cell or performing a write operation of a memory cell may include an operation or a process that modifies the memory state the memory cell is residing in from a (e.g., first) memory state to another (e.g., second) memory state. According to various aspects, writing a memory cell may include programming a memory cell (e.g., performing a programming operation of a memory cell), wherein the memory state the memory cell is residing in after programming may be called “programmed state”. For example, programming an n-type FET based memory cell may modify the state the memory cell is residing in from the HVT state to the LVT state, whereas programming a p-type FET based memory cell may modify the state the memory cell is residing in from the LVT state to the HVT state. According to various aspects, writing a memory cell may include erasing a memory cell (e.g., performing an erasing operation of a memory cell), wherein the memory state the memory cell is residing in after the erasing may be called “erased state”. For example, erasing an n-type FET based memory cell may modify the state the memory cell is residing in from the LVT state to the HVT state, whereas erasing a p-type FET based memory cell may modify the state the memory cell is residing in from the HVT state to the LVT state.

Another example of a memory cell having at least two distinct states is a phase-change memory cell. The phase-change memory cell may include a phase change portion. The phase-change portion may be used to implement memory functions, e.g., in a memory cell. The phase-change portion may include a first phase state and a second phase state. For example, a phase-change memory cell may change from a first phase state to a second phase state or vice versa upon applying an electrical signal and may remain in the respective phase state for at least some time (referred to as retention time).

With reference to FIG. 1C, the memory structure 100 may be configured as a 1C1T (one capacitor, one transistor) memory cell. In this case the memory structure 100 may also be referred to as 1C1T ferroelectric capacitive memory (FCM) and/or as (e.g., non-volatile) FERAM. In this case, the first electrode 126 of the SPOC structure 120 may be coupled to the first terminal 104 (as exemplarily shown in FIG. 1C) or to the second terminal 106. An access device, such as the field-effect transistor structure 110 (may also be referred to as access transistor), may allow to control an electrical behavior (e.g., a resistance R) of the channel region 112, thereby allowing to write the memory cell (by storing a charge in the capacitor of the SPOC structure 120) and/or read the memory cell (by detecting a voltage and/or current representing the charge stored in the capacitor of the SPOC structure 120). In this case, the second electrode 128 of the SPOC structure 120 may be connected to or may form a SPOC structure terminal 107.

According to various aspects, a memory device may include a memory cell and a controller (e.g., a memory controller) configured to operate (e.g., read and write) the memory cell. According to various aspects, a memory cell arrangement may include a memory cell and a controller (e.g., a memory controller) configured to operate (e.g., read and write) the memory cell. It is noted that some aspects are described herein with reference to a memory cell of a memory device and/or with reference to a memory cell of memory cell arrangement; it is understood that a memory device and/or a memory cell arrangement may include a plurality of such described memory cells according to various aspects that can be operated in the same way by the controller, e.g., at the same time or in a time sequence. A memory cell arrangement may further include respective sets of control lines and voltage supply levels configured to operate the one or more memory cells of the memory device and/or the memory cell arrangement.

It is noted that a memory cell arrangement is usually configured in a matrix-type arrangement, wherein columns and rows define the addressing of the memory cells according to the control lines connecting respectively subsets of memory cells of the memory cell arrangement along the rows and columns of the matrix-type arrangement. However, other arrangements may be suitable as well.

In general, a memory cell arrangement may include a plurality of (e.g., volatile or non-volatile) memory cells, which may be accessed individually or on groups via a corresponding addressing scheme. The matrix architecture may be, for example, referred to as “OR”, “AND”, “NOR”, or “NAND” architecture, depending on the way neighboring memory cells are connected to each other, i.e., depending on the way the terminals of neighboring memory cells are shared, but are not limited to these two types (another type is for example an “AND” architecture). For example, in a NAND architecture the memory cells may be organized in sectors (also referred to as blocks) of memory cells, wherein the memory cells are serially connected in a string (e.g., source and drain regions are shared by neighboring transistors), and the string is connected to a first control line and a second control line. For example, groups of memory cells in a NAND architecture may be connected in series with one another. In a NOR architecture the memory cells may be connected in parallel with one another. A NAND architecture may thus be more suited for serial access to data stored in the memory cells, whereas a NOR architecture may be more suited for random access to data stored in the memory cells.

The memory cell described herein (e.g., as part of a memory cell arrangement) may be used in connection with any type of suitable controller, e.g., a controller that may generate only two or only three different voltage levels for writing the memory cell (e.g., for writing one or more memory cells of a memory cell arrangement). However, in other aspects, more than four different voltage levels may be used for operating (e.g., for reading) the memory cell or for operating one or more memory cells of a memory cell arrangement.

According to various aspects, the memory cell described herein may be configured complementary metal oxide semiconductor (CMOS) compatible, e.g., including standard CMOS-materials only and may require no special integration considerations (e.g., no special thermal budget which may avoid diffusion and/or contamination during manufacturing). CMOS compatible spontaneously polarizable materials may be used to implement the one or more memory cells based on, for example, HfO₂ and/or ZrO₂. Doped HfO₂ (e.g., Si:HfO₂ or Al:HfO₂) or other suitable spontaneously-polarizable materials may allow for an integration of the spontaneously polarizable layer via known integration schemes.

According to various aspects, a controller may be configured to provide one or more sets of voltage levels to operate a memory cell arrangement (e.g., including a plurality of memory cells). According to various aspects, a writing operation may be provided based on only two voltage levels (e.g., a first supply voltage level VPP and a second supply voltage level VNN). In the case that the CMOS technology provides electrical access to the bulk, all bulks may be connected to VNN or a voltage significantly similar to VNN but such that no diode from bulk to any source/drain region is forward biased.

FIG. 1D schematically shows an exemplary memory cell arrangement 101 including two-terminal memory cells according to various aspects. Each two-terminal memory cell 102 may be configured as described with reference to FIG. 1A. The memory cell arrangement 101A may include an array of N times M memory cells. “N” may be any integer number equal to or greater than one. “M” may be any integer number equal to or greater than one.

The memory cell arrangement 101A may include a first set of control lines CL1(n=1 to N) and a second set of control lines CL2(m=1 to M) for individually addressing one or more of the memory cells.

The memory cell arrangement 101A may include a control circuit 103 (e.g., including a read-out circuit and/or a write circuit). The control circuit 103 may be configured to apply a first voltage at the first terminal 121 of a memory cell 102(m, n) via the corresponding control line CL1(n) of the first set of control lines and to apply a second voltage at the second terminal 123 of the memory cell 102(m, n) via the corresponding control line CL2(m) of the second set of control lines in order to address the memory cell 102(m, n).

FIG. 1E schematically shows the exemplary memory cell arrangement 101 including three-terminal memory cells according to various aspects. Each three-terminal memory cell 102 may be configured as described with reference to FIG. 1B or FIG. 1C.

The memory cell arrangement 101B may include a plurality, n, of first control lines, for example, a plurality of sourcelines SL (n). The memory cell arrangement 101B may include a plurality, n, of second control lines, for example, a plurality of drainlines DL (n). The memory cell arrangement 101B may include a plurality, m, of third control lines, for example, a plurality of wordlines WL (m). For each memory cell 102(m, n) of the plurality of memory cells, the first terminal 104 may be connected to a corresponding sourceline SL (n), the second terminal 106 may be connected to a corresponding drainline DL (n), and the third terminal 108 may be connected to a corresponding wordline WL (m).

The control circuit 103 may be configured to apply a first voltage, Vs, at the first terminal 104, a second voltage, VD (e.g., a base voltage), at the second terminal 106, and a third voltage, VG, at the third terminal 108 of a memory cell 102(m, n) in order to address the memory cell 102(m, n).

It is understood that these configurations of the memory cell arrangement 101 serve as examples and that the memory cells 102 may be part of any suitable memory cell arrangement including corresponding control lines for addressing the memory cells 102. Further, it is understood that a memory cell arrangement may include further components such as one or more access devices for addressing the memory cells.

Herein, various exemplary configurations of the SPOC structure 120 are provided according to various aspects. For illustration, various of the configurations of the SPOC structure 120 are exemplarily shown for a planar configuration with planar layers. It is noted that other shapes may be suitable as well, such as curved shapes, angled shapes, coaxially aligned shapes, as examples. In this case, any layer described herein may have a non-planar (e.g., curved) structure. According to various aspects, the SPOC structure 120 may conformally cover a three-dimensional structure. Thus, the shape of the SPOC structure 120 may depend on (e.g., may substantially correspond to) the shape of this three-dimensional structure.

The phrase that “a layer conformally covers a structure” or that “a layer is disposed conformally over a structure” may be understood to mean that a thickness, which is measured normal (e.g., perpendicular) to a surface of the structure (e.g., the three-dimensional structure described herein), is substantially constant along the surface.

In various scenarios, it may be desired or even necessary to form one or more layers conformally over or on a three-dimensional structure, such as a trench. Here, ALD may be advantageous over other deposition methods (such as physical vapor deposition methods). In some cases, e.g., when a feature size (e.g., an aspect ratio) of the three-dimensional structure is equal to or greater than a threshold value (e.g., an aspect ratio equal to or greater than ten), ALD may even be required in order to form the one or more layers conformally over the three-dimensional structure (e.g., conformally within the trench).

According to various aspects, the three-dimensional structure may have a feature size (e.g., an aspect ratio) equal to or greater than six (e.g., equal to or greater than ten, e.g., equal to or greater than fifteen, e.g., equal to or greater than twenty, etc.)

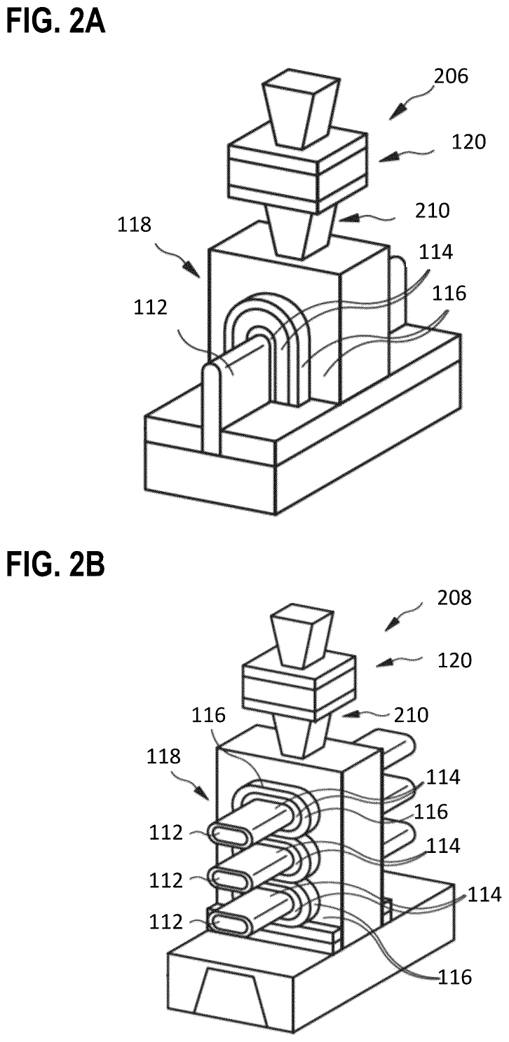

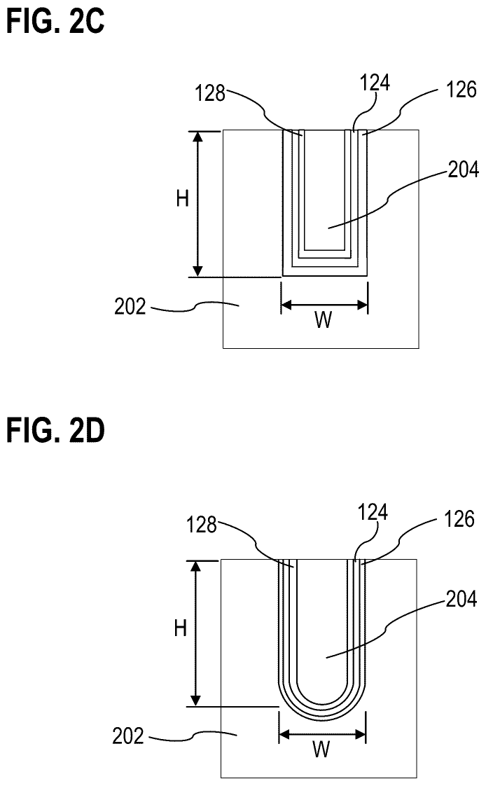

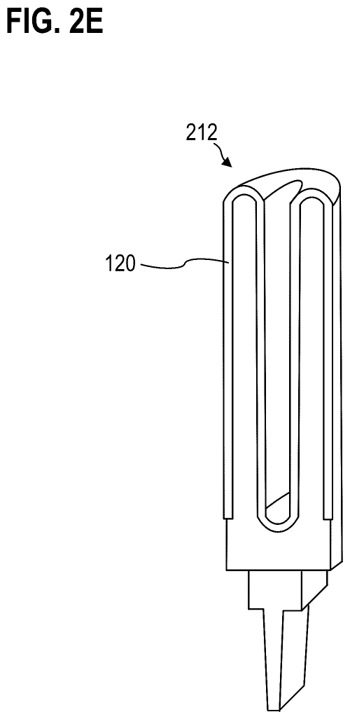

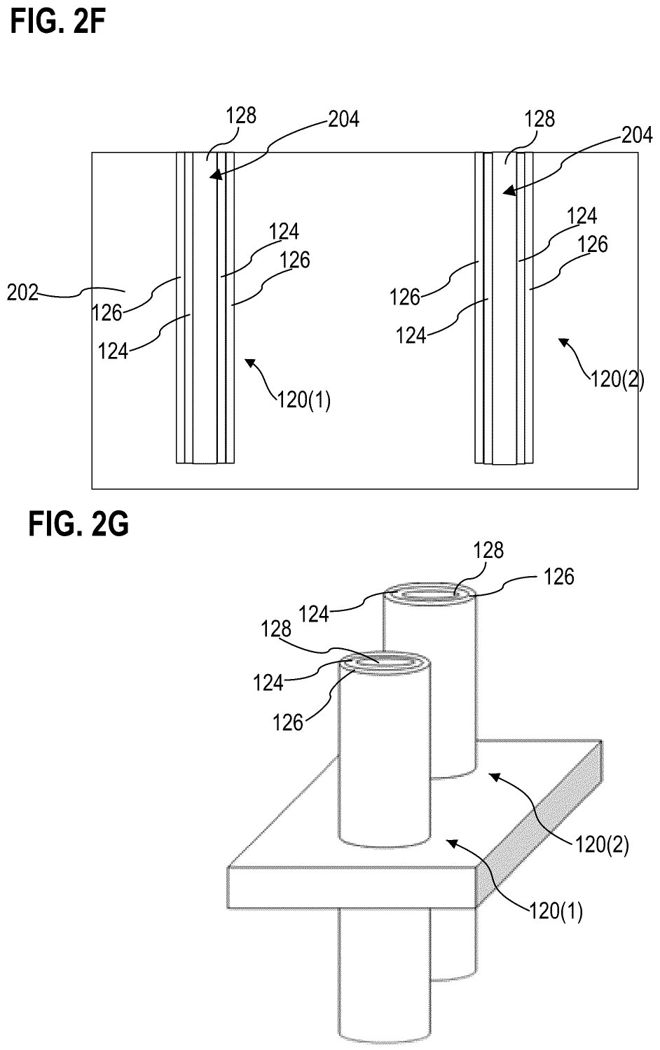

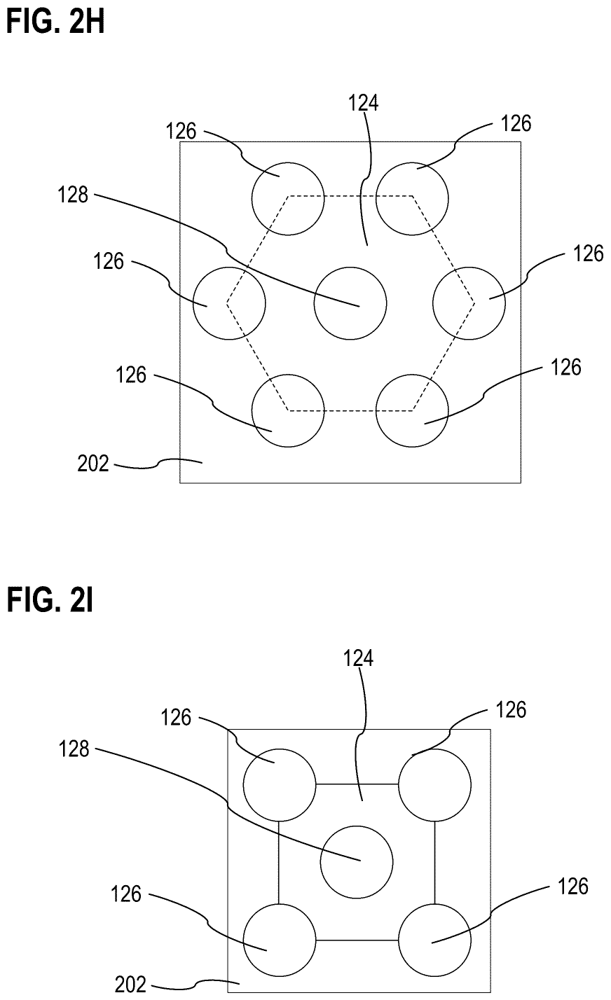

In various cases (e.g., in the exemplary case that the three-dimensional structure is a trench), the feature size may be given by the aspect ratio. The aspect ratio, may be defined by a ratio between the height, H, (which may also be referred to as depth) and the width, W (i.e., a=H/W) of the three-dimensional structure. The width, W, may be measured (e.g., in the case of a curved trench as shown in FIG. 2D) at the surface of the substrate. Thus, in the case of a circular trench, the width, W, may be a diameter of an opening of the circular trench at the surface of the substrate.

However, it is understood that the threshold value at which ALD may be required in order in order to form the one or more layers conformally over the three-dimensional structure may also depend on the width of the three-dimensional structure itself. For example, the width of the three-dimensional structure (e.g., as measured at the surface of the substrate in the case of a trench) may be equal to or less than 200 nm, e.g., equal to or less than 100 nm, e.g., equal to or less than 50 nm (e.g., in combination with the aspect ratio described herein).

It is understood that atomic layer deposition (ALD) generally forms a layer conformally. Thus, in the case that herein a layer is formed over a structure using ALD, the layer is understood to be formed conformally over the structure. Hence, a layer formed over a structure using ALD conformally covers the structure.

FIG. 2A to FIG. 2I each show at least one spontaneously polarizable capacitor structure conformally covering a three-dimensional structure according to various aspects. It is understood that these structures serve for illustration and that the three-dimensional (3D) structure may be another 3D structure (e.g., requiring ALD to form a layer which conformally covers a surface of the 3D structure).

As an example, FIG. 2A shows an integration scheme of a memory cell 102 which may be configured as a fin field-effect transistor (FinFET). The substrate portion in which the channel region 112 is provided may have the shape of a vertical fin, wherein the gate isolation 114 and the gate electrode 116 may at least partially surround the fin. As a further example, FIG. 2B shows a memory cell 102 which may be configured as a nanosheet or nanowire field-effect transistor (also referred to as gate-all-around (GAA) FinFET). The substrate portion(s), in which a respective channel region 112 is provided, may each have the shape of a nanosheet or nanowire. The gate isolation 114 and the gate electrode 116 may at least partially surround the respective nanosheets or nanowires.

Although the SPOC structure 120 of FIG. 2A and FIG. 2B is shown as being substantially planar, it is understood that the SPOC structure may also be non-planar (e.g., conformally disposed within or over the substrate portion 202. These two integration schemes may be configured as detailed with reference to FIG. 1B. For example, the SPOC structure 120 may be integral with the (metal) gate structure 118, e.g., disposed conformally over the (metal) gate structure 118. As an example with reference to the FinFET shown in FIG. 2A, the layers of the SPOC structure 120 may be disposed directly (e.g., conformally) over the gate structure 118. The metal gate structure 118 may, for example, be a replacement metal gate (RMG). As an example with reference to the GAA FinFET shown in FIG. 2B, a portion of the gate dielectric 114 and gate electrode 116 may be disposed around each nanosheet (or nanorods in other aspects) and the layers of the SPOC structure 120 may be disposed conformally around each of these portions.

FIG. 2C and FIG. 2D each show, for illustration, a trench 204 as three-dimensional structure within a substrate portion 202. The SPOC structure 120 may be disposed within the trench 204. The layers of the SPOC structure 120 may be disposed conformally over the substrate portion 202 (i.e., may cover the substrate portion 202 conformally). The trench 204 is shown in FIG. 2C as having a substantially rectangular shape. It is understood that this serves for illustration and that the trench 204 may have another shape. For example, at least a section of an inner wall of the trench 204 may be curved. As an example, a bottom portion of the trench 204 may be curved (see, for example, FIG. 2D). It is understood that the bottom surface and/or top surface of the trench 204 may have any suitable shape, such as one of the following: a circle, a square, a triangle, a parallelogram, a trapezoid, an ellipse, a polygon. The trench 204 may have an aspect ratio equal to or greater than a threshold value (e.g., equal to or greater than six (e.g., equal to or greater than ten, e.g., equal to or greater than fifteen, etc.). As detailed herein, conformally forming the SPOC structure 120 within a trench 204 having an aspect ratio equal to or greater than the threshold value may require atomic layer deposition.

It is understood that the trench 204 serves as an example for illustration and that a “three-dimensional structure”, as described herein, may be any kind of three-dimensional structure such as a nanowire or nanoparticles on a surface of a substrate, or a surface of a porous substrate. A three-dimensional structure may be part of a ferroelectric tunnel junction and/or a selector element. It is understood that these three-dimensional structures are examples for illustration and that the SPOC structure 120 can be formed over other three-dimensional structures by employing the principles describes herein.

As an even further example, FIG. 2E shows a cross-section of an exemplary configuration in which the SPOC structure 120 is disposed on and/or within a cup 212. The cup 212 may be a (hollow) cylindrical structure similar to the ones of a (advanced) dynamic random-access memory (DRAM).

As another example, FIG. 2F shows a cross-section of an exemplary arrangement of two SPOC structures 120(1), 120(2) within a cylindrical trench according to various aspects. FIG. 2G shows a perspective view thereof. As shown, in this scenario the SPOC structure 120 may have a cylindrical shape.

As another example, FIG. 2H shows a top view on an exemplary SPOC structure 120 having a honeycomb-like structure (as indicated by the dashed hexagon). It is understood that the SPOC structure 120 may have a shape in accordance with any other polygon (e.g., having any other number of circular-shaped elements). For example, the SPOC structure 120 may include the circular-shaped elements with a square periodicity as shown in FIG. 2I. Further, according to various aspects, the circular-shaped elements (e.g., of the honeycomb structure and/or the square structure) may be connected to each other via one or more further structures. These further structure may, for example, serve as a support structure and/or as an electrically conductive connection.

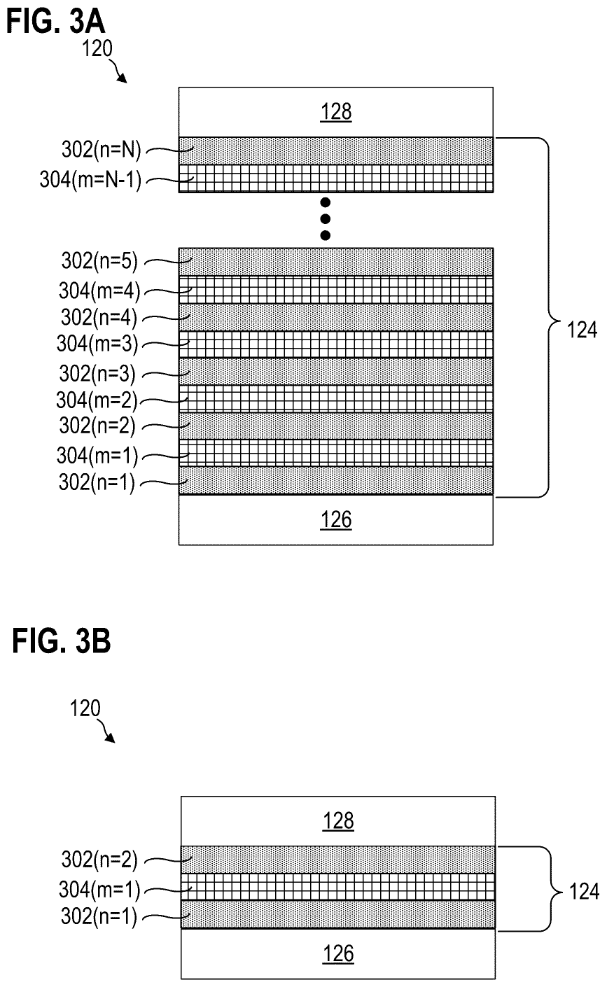

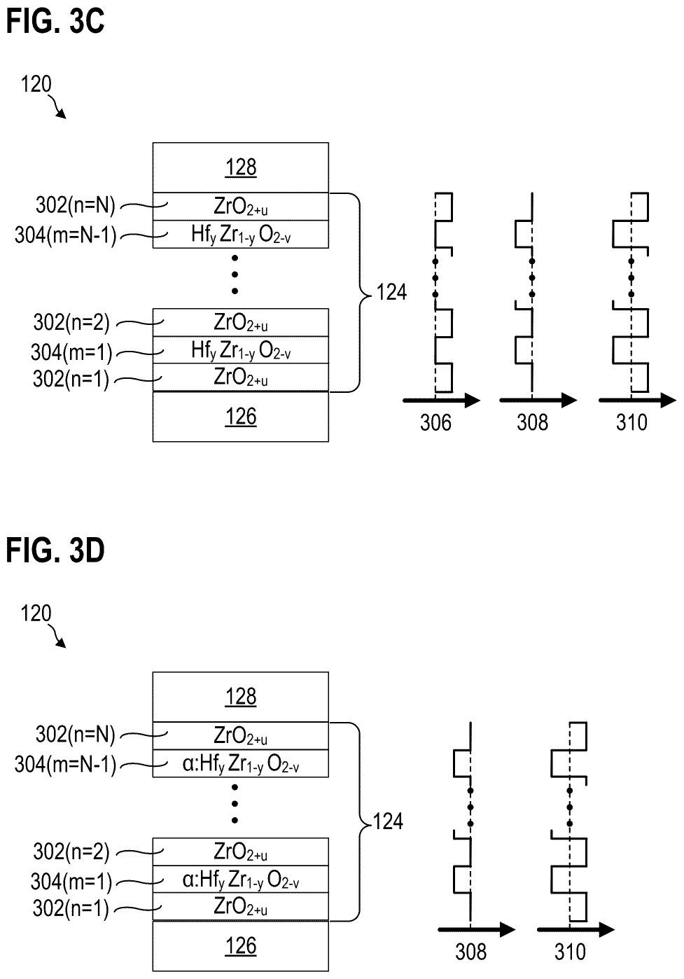

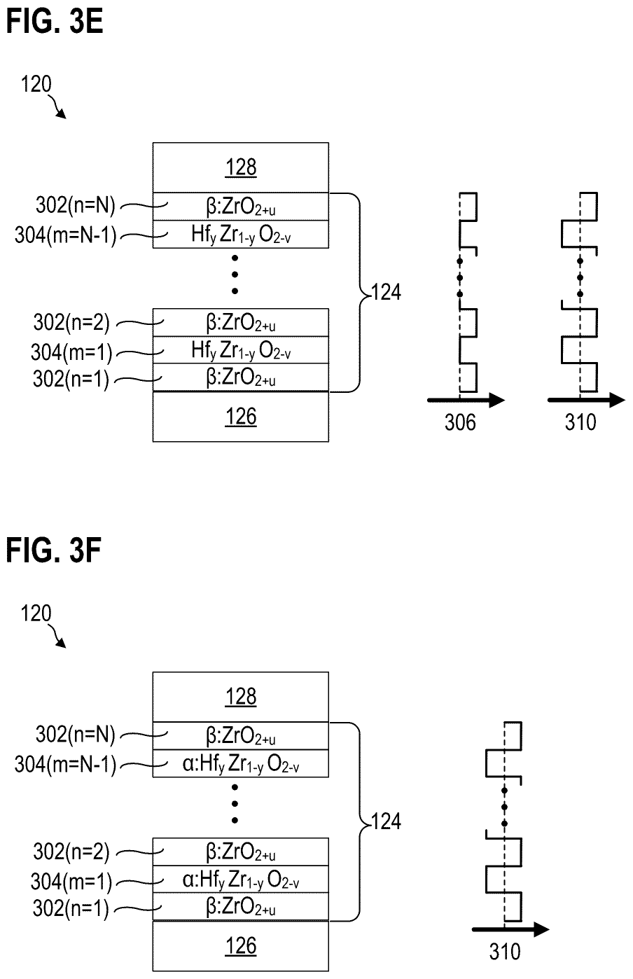

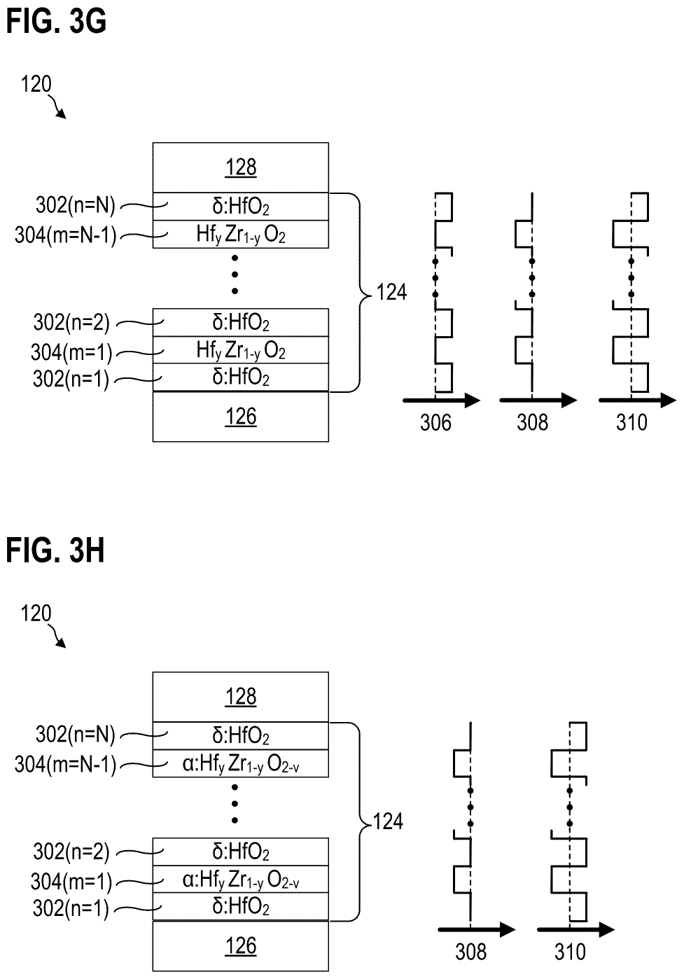

FIG. 3A to FIG. 3H each show an exemplary configuration of the SPOC structure 120 according to various aspects. As described, the SPOC structure 120 may include the memory element 124, the first electrode 126 (which may also be referred to as bottom electrode), and the second electrode 128 (which may also be referred to as top electrode).

The first electrode 126 and the second electrode 128 may be electrically conductive. The first electrode 126 and/or the second electrode 128 may include one or more electrically conductive layers. Such an electrically conductive layer may substantially consist of a metal or a (electrically conductive) metal nitride. The metal and/or the metal of the metal nitride may be, for example, a metal of the following list of metals: Copper (Cu), Platinum (Pt), Iridium (Ir), Rhenium (Re), Rhodium (Rh), Palladium (Pd), Ruthenium (Ru), Titanium (Ti), Osmium (Os), Molybdenum (Mo), Chromium (Cr), Tungsten (W), Silver (Ag), Aluminum (Al), Gold (Au), Cobalt (Co), etc. The metal nitride may be, for example, a titanium-based alloy (e.g., TiN, Ti—C—N, Ti—Al—N, TiN—TaN, etc.), a tantalum-based alloy (e.g., TaN, Ta—C—N, TaN—TiN), or a tungsten-based nitride (e.g., WN). In some aspects, the first electrically conductive electrode layer 132 and the second electrically conductive electrode layer 136 may be made of a same material. In other aspects, the first electrically conductive electrode layer 132 and the second electrically conductive electrode layer 136 may be made of different materials.

In some aspects, the electrically conductive layer may include or may consist of an oxidation resistant metal (e.g., a noble metal). The oxidation resistant metal may have an electronegativity greater than 1.85 on the Pauling scale. The oxidation resistant metal may have a melting temperature greater than 1450° C. This may reduce an oxidation of the interface of the second electrically conductive electrode layer 136. The oxidation resistant metal may include (e.g., consist of), for example, tungsten, platinum, iridium, ruthenium, palladium, osmium, rhodium, molybdenum, cobalt, rhenium, or nickel. According to various aspects, the first electrically conductive electrode layer 132 and/or the second electrically conductive electrode layer 136 may have a work function of the oxidation resistant metal equal to or greater than 5 eV. According to various aspects, using oxidation resistant metal electrode(s) in combination with a spontaneously polarizable material which includes transition-metal-oxides (e.g., as a high-k capacitor dielectric) may suppress a charge injection due to the work function equal to or greater than 5 eV and a comparatively high band-offset. The band-offset may be a conduction band-offset for electrons (between Fermi-level of the electrode and the conduction band of the dielectric layers) or a valance band offset for holes (between Fermi-level of the electrode and the valence band of the dielectric layers).

With reference to FIG. 3A and FIG. 3B, the memory element 124 may include a spontaneously polarizable memory layer stack. This spontaneously polarizable memory layer stack may have spontaneously polarizable properties. The spontaneously polarizable memory layer stack may include an alternating sequence of first sublayers 302(n=1 to N) and second sublayers 304(m=1 to M). The alternating sequence may start with one 302(n=1) of the first sublayers and ends with another one 302(n=N) of the first sublayers. In this case, “N” may be any integer number equal to or greater than two and “M” may be any integer number equal to or greater than one (with M=N−1). A configuration for N=2 is shown in FIG. 3B. The first sublayer 302(n=1) with which the alternating sequence starts and the first sublayer 302(n=N) with which the alternating sequence ends may have a same thickness. This may improve the electronic properties (e.g., the polarization switching properties) of the SPOC structure 120. According to various aspects, each of the first sublayers has a same thickness and/or each of the second sublayers has a same thickness. This may also improve the electronic properties.

The first sublayers may substantially consist of a material having antiferroelectric properties (e.g., hafnium oxide or zirconium oxide) and the second sublayers may substantially consist of a material having ferroelectric properties (e.g., hafnium zirconium oxide). The antiferroelectric first sublayers within the ferroelectric second sublayers induce a phase competition, thereby reducing the coercive field of the spontaneously polarizable memory layer stack

In general, hafnium zirconium oxide (Hf_{1-y}Zr_{y}O₂, HZO) with 0<y<1 has several advantages for CMOS integration:
HZO films are ferroelectric or antiferroelectric down to a thickness of 1 nm. Hence, the integration of the SPOC structure 120 in lateral dimension is scalable to a maximum degree.
HZO films can be deposited using ALD. This allows to manufacture SPOC structure 120 having curved structures and allow a 3D-integration of the SPOC structure 120.
HZO films are CMOS compatible and do not include any toxic elements. Hence, an encapsulation of the SPOC structure 120 may be optional and the standard CMOS equipment can be used.
It may be possible to crystallize the HZO into the ferroelectric phase by annealing at temperatures in a range from about 300° C. to about 400° C. This allows an integration of the SPOC structure 120 as part of the interlayer metallization.
HZO films have a large band gap (e.g., 5.8 eV for hafnium oxide). Thus, HZO can be used for devices that require a low leakage current.

It has been found that, when using stoichiometric zirconium oxide (ZrO₂) as first sublayers and stochiometric HZO as second sublayers there may be several advantages in terms of electronic properties, but also leakage which can lead to discharging of the capacitor, increased power consumption during (polarization) switching, higher stress operation and, hence, accelerated breakdown. In this context, it has been found that the leakage can be significantly reduced (e.g., suppressed) by engineering the oxygen concentration (e.g., by using over-stoichiometric zirconium oxide and/or under-stoichiometric HZO as shown in FIG. 3C to FIG. 3F) and/or by replacing zirconium oxide with antiferroelectric hafnium oxide (see FIG. 3G and FIG. 3H). In the following, these two alternatives for reducing leakage in the spontaneously polarizable memory layer stack are detailed.

With reference to FIG. 3C to FIG. 3F, the first sublayers 302(n=1 to N) may substantially consist of (e.g., doped or undoped) zirconium oxide (ZrO₂₊ᵤ) and second sublayers 304(m=1 to M) may substantially consist of (e.g., doped or undoped) HZO (Hf_{y}Zr_{1-y}O₂₋ᵥ) (with y<1). It has been found that the leakage can be reduced in the case that an (first) oxygen concentration of the zirconium oxide is substantially greater than an (second) oxygen concentration of the HZO. This can be, for example, achieved by using (e.g., doped or undoped) over-stoichiometric zirconium oxide (ZrO₂₊ᵤ with u>0) and/or by using (e.g., doped or undoped) under-stoichiometric HZO (Hf_{y}Zr_{1-y}O₂₋ᵥ with v>0).

According to various aspects, “u” may be equal to or greater than 0.1 (e.g., equal to or greater than 0.2). Thus, the first oxygen concentration of each first sublayer 302(n) may be over-stoichiometric by at least 5% (i.e., u≥0.1) (e.g., over-stoichiometric by at least 10%). In this case, the first oxygen concentration may be equal to or greater than about 67.7 at. % (for ZrO₂₊ᵤ with u≥0.1). For example, the first oxygen concentration may be equal to or greater than about 68.7 at. % (for ZrO₂₊ᵤ with u≥0.2).

According to various aspects, “v” may be equal to or greater than 0.1 (e.g., equal to or greater than 0.2). Thus, the second oxygen concentration of each second sublayer 304(m) may be under-stoichiometric by at least 5% (i.e., u≥0.1) (e.g., under-stoichiometric by at least 10%). In this case, the second oxygen concentration may be equal to or less than about 65.5 at. % (for Hf_{y}Zr_{1-y} O₂₋ᵥ with v>0.1). For example, the second oxygen concentration may be equal to or less than about 64.3 at. % (for Hf_{y}Zr_{1-y} O₂₋ᵥ with u≥0.2).

Thus, the first oxygen concentration of each first sublayer 302(n) may be at least 1 at. % (e.g., 1 at. % or more than 1 at. %, such as 2 at. % or more than 2 at. %) greater than the second oxygen concentration of the HZO. According to various aspects, first oxygen concentration of each first sublayer 302(n) may be at least 2 at. % greater than the second oxygen concentration of the HZO. It has been found that the leakage can be reduced significantly in the case that the first oxygen concentration of each first sublayer 302(n) is at least 2 at. % greater than the second oxygen concentration of each second sublayer 304(m). This may be achieved by using:
stoichiometric HZO (with v=0) and over-stoichiometric zirconium oxide (with u≥0.2); or
stoichiometric zirconium oxide (with u=0) and under-stoichiometric HZO (with v≥0.2); or
over-stoichiometric zirconium oxide and under-stoichiometric HZO (with u+v≥0.2).

This results in an improved ferroelectric performance in the second sublayers (hence, the HZO) and a leakage prevention in the first sublayers (hence, zirconium oxide).

Herein, two options (which can be combined) are provided for adjusting the oxygen concentration of a respective sublayer (of the first and/or second sublayers): As a first option, the oxidation process may be adjusted to increase or decrease the oxygen concentration as compared to the stoichiometric oxygen concentration. As a second (additional or alternative) option, the respective sublayer may be doped to increase or decrease the oxygen concentration.

With reference to FIG. 3C, each first sublayer 302(n) may substantially consist of undoped zirconium oxide and each second sublayer 304(m) may substantially consist of undoped HZO. In this case, three different oxygen concentration profiles can be achieved:
a first oxygen concentration profile 306 characterized by stoichiometric HZO (with v=0) and over-stoichiometric zirconium oxide (with u≥0.1, e.g., u≥0.2);
a second oxygen concentration profile 308 characterized by stoichiometric zirconium oxide (with u=0) and under-stoichiometric HZO (with v≥0.1, v≥0.2);
a third oxygen concentration profile 310 characterized by over-stoichiometric zirconium oxide and under-stoichiometric HZO (with u+v≥0.1, u+v≥0.2).

The dashed line indicates the stoichiometric oxygen concentration (i.e., u=0 and v=0).

As detailed herein, the first oxygen concentration may be (e.g., further) increased by doping each first sublayer 302(n) and/or the second oxygen concentration may be (e.g., further) decreased by doping each second sublayer 304(m). The doping disclosed herein may be employed in addition to the oxidation process or as an alternative.

There may be the following configurations of the SPOC structure 120 when doping the first sublayers and/or the second sublayers:
each first sublayer 302(n) may be undoped and each second sublayer 304(m) may be doped with at least one second dopant α (see, for example, FIG. 3D);
each first sublayer 302(n) may be doped with at least one first dopant β and each second sublayer 304(m) may be undoped (see, for example, FIG. 3E);
each first sublayer 302(n) may be doped with the at least one first dopant β and each second sublayer 304(m) may be doped with the at least one second dopant α (see, for example, FIG. 3F).

According to various aspects, the at least one first dopant β may be or may include a group-5-element, such as Niobium (Nb), Vanadium (V), and/or Tantalum (Ta). It has been found that Niobium (Nb) leads to a greatest reduction of leakage in the first sublayers. In some aspects, the zirconium oxide may be doped with more than one element (e.g., more than one group-5-element).

According to various aspects, the at least one second dopant α may be or may include Lanthanum (La) or a group-3-element, such as Scandium (Sc), Yttrium (Y), Lutetium (Lu), and/or Lawrencium (Lr). It has been found that Lanthanum (La) leads to a greatest improvement of electronic properties of the SPOC structure 120.

For illustration, the first oxygen concentration profile 306 and the second oxygen concentration profile 308 are illustrated in FIG. 3D to FIG. 3E similar to FIG. 3C such that the undoped sublayer is indicated to have the stoichiometric oxygen concentration. However, it is noted that decreasing the oxygen concentration via doping one of the sublayers may initiate a migration of oxygen to the neighboring sublayers, thereby increasing their oxygen concentration. For example, doping each second sublayer 304(m) with Lanthanum (La as second dopant a) may generate (and fixate) oxygen vacancies with the HZO. The surplus of oxygen ions may then migrate into the first sublayers, thereby increasing the oxygen concentration.

As detailed herein, the leakage may be reduced by using antiferroelectric hafnium oxide (instead of (antiferroelectric) zirconium oxide). FIG. 3G and FIG. 3H each show an exemplary configuration of the SPOC structure 120 in which each first sublayer 302(n) substantially consists of antiferroelectric hafnium oxide (HfO₂).

The crystal structure of hafnium oxide may be one of: monoclinic (also referred to as low-symmetry phase), tetragonal (also referred to as high-symmetry phase), or orthorhombic (also referred to as intermediate phase). The orthorhombic crystal structure of hafnium oxide is ferroelectric and the tetragonal crystal structure is antiferroelectric. Thus, when referring to antiferroelectric hafnium oxide, the hafnium oxide may have the tetragonal crystal structure.

In order to achieve the antiferroelectric hafnium oxide, the hafnium oxide may be doped with at least one third dopant δ which stabilizes the tetragonal crystal structure. In some aspects, the at least one third dopant δ may be or may include Silicon (Si) and/or Aluminum (Al). Additionally or alternatively, the at least one third dopant δ may be or may include one or more of: Lanthanum (La), Yttrium (Y), Niobium (Nb), and/or Gadolinium (Gd).

Using antiferroelectric hafnium oxide as material of the first sublayers may be combined with the adjusting the oxidation process to increase the first oxygen concentration of hafnium oxide (i.e., using over-stoichiometric hafnium oxide (HfO₂₊ᵤ)) and/or to decrease the second oxygen concentration as detailed above. This is also indicated by the first oxygen concentration profile 306, the second oxygen concentration profile 308, and the third oxygen concentration profile 310 in FIG. 3G and FIG. 3H. Also, the HZO of each second sublayer 304(m) may be doped with the second dopant β (see FIG. 3H).

According to various aspects, a memory cell arrangement may include a plurality of memory cells each including the SPOC structure 120 described herein. The memory cell arrangement may be, for example, a ferroelectric random-access memory (FeRAM), a ferroelectric non-volatile random-access memory (FeNVRAM), a dynamic random-access memory (DRAM), etc.

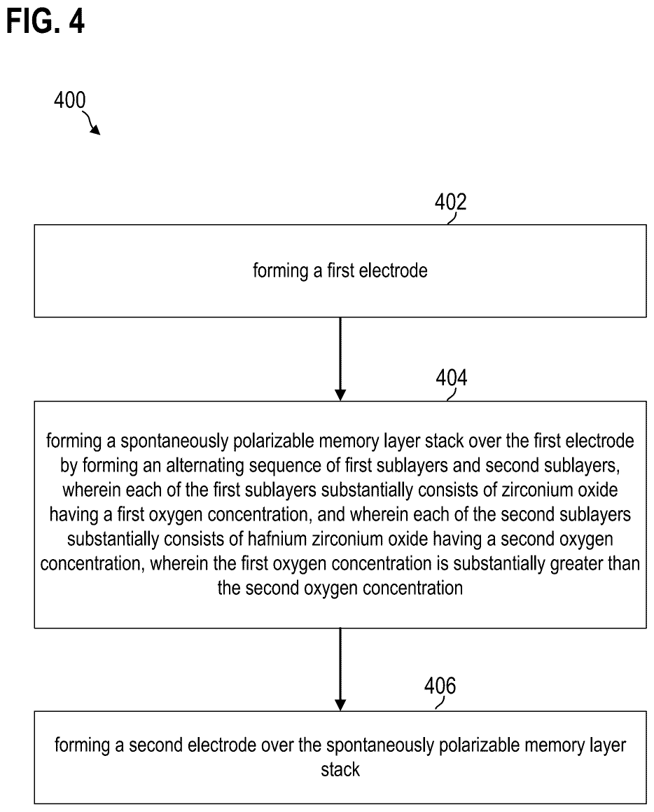

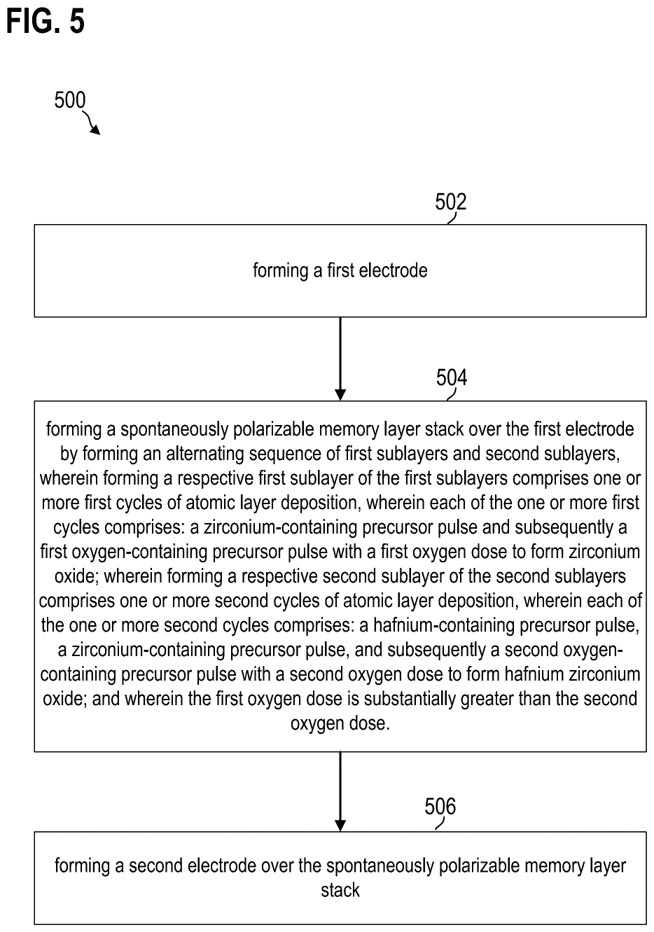

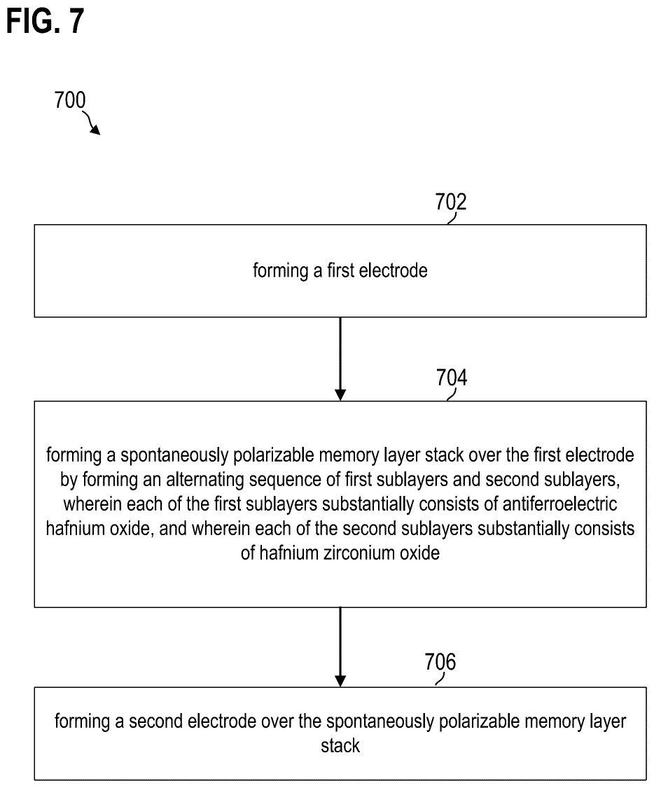

FIG. 4 to FIG. 7 each show a respective flow diagram of a method 400, 500, 600, 700 respectively, of manufacturing a memory capacitor according to various aspects.

Each of the methods 400, 500, 600 may include forming a first electrode (e.g., the first electrode 126) (e.g., over the substrate portion 202) (in 402, 502, 602, 702, respectively).

Each of the methods 400, 500, 600 may include forming spontaneously polarizable memory layer stack (e.g., to provide the memory element 124) over the first electrode (in 404, 504, 604, 704, respectively). The spontaneously polarizable memory layer stack may be formed by forming an alternating sequence of first sublayers and second sublayers.

Each of the methods 400, 500, 600 may include forming a second electrode (e.g., the second electrode 128) over the spontaneously polarizable memory layer stack (in 406, 506, 606, 706, respectively). The first electrode, the spontaneously polarizable memory layer stack, and the second electrode may form a memory capacitor (e.g., the SPOC structure 120).

The memory capacitor may include a SPOC structure 120 as detailed with reference to FIG. 3C to FIG. 3F.

With reference to method 400, each of the first sublayers may substantially consist of zirconium oxide having a first oxygen concentration, and each of the second sublayers may substantially consist of hafnium zirconium oxide having a second oxygen concentration. The first oxygen concentration may be substantially greater than the second oxygen concentration.

An electrode (e.g., the first electrode and/or the second electrode) may be formed using atomic layer deposition (ALD) or a vapor deposition different from ALD (e.g., a physical vapor deposition (PVD), such as sputtering, or chemical vapor deposition (CDV) different from ALD).

According to various aspects, the first sublayers and/or the second sublayers may be formed using ALD. In general, an atomic layer deposition (ALD) of a layer may include various cycles and/or sub-cycles. Each cycle may include one or more precursor pulses and a respective purging after each precursor pulse of the one or more precursor pulses. A precursor pulse may be associated with injecting a gas which includes a respective material of one or more materials to be deposited into a processing chamber in which the memory capacitor is (or is to be) processed. A precursor pulse may be associated with a pulse time defining a time for which the gas is injected into the processing chamber. Each pulse, described herein, may also be associated with a respective process temperature representing a temperature of the substrate and/or the already formed part of the memory capacitor. After each precursor pulse of the one or more precursor pulses, a respective purging may be carried out. Hence, for example, a purging may be carried out between a precursor pulse and a consecutive pulse of an oxidizer (in the case of depositing an oxide layer), or vice versa. A purging may include a purging of remaining gas associated with the respective pulse (e.g., precursor pulse or oxidizer pulse). The purging of the remaining gas may include a purging with another gas, such as nitrogen (N₂). Alternatively, such as in the case of spatial ALD, gas barriers (e.g., a N₂ barrier) may be used instead of purging. Thus, it is understood that between two consecutive pulses described herein (e.g., between a precursor pulse and an oxidizer pulse, or vice versa), a purging may be carried out and/or the substrate may be moved through a gas barrier (e.g., into another chamber).

Forming a first sublayer substantially consisting of a transition-metal-oxide (e.g., hafnium oxide or zirconium oxide) may include injecting a precursor gas which includes the transition metal into the processing chamber. It is understood that the precursor gas may include other components as well; however, the precursor gas may be configured such that after purging atoms of the transition metal (and optionally further one or more ligands) are deposited at a surface of the processed memory capacitor (the ligands may be reacted (e.g., oxidized) away by a subsequent (e.g., oxygen-containing) precursor pulse). For example, the transition metal may be hafnium and the precursor gas may include hafnium, such as Tetrakis-(ethylmethylamido)-hafnium (TEMA-Hf) or Tetrakis-(dimethylamido)-hafnium (TDMA-Hf). For example, the transition metal may be zirconium and the precursor gas may include zirconium, such as Tetrakis-(ethylmethylamido)-zirconium (TEMA-Zr) or Tetrakis-(dimethylamido)-zirconium (TDMA-Zr). Any chemistry associated with the atomic layer deposition capable to remove ligands of the respective precursor may be used.

An atomic layer of a layer, which includes an oxide, may be formed by a respective precursor pulse of one or more materials and an oxygen-containing pulse (in some aspects referred to as oxidizer pulse) to oxidize the one or more materials.

Forming a first sublayer substantially consisting of HZO may include at least one hafnium-containing precursor pulse (e.g., TEMA-Hf or TDMA-Hf), at least one zirconium-containing precursor pulse (e.g., TEMA-Zr or TDMA-Zr), and at least one oxygen-containing pulse to oxidize the hafnium and zirconium.

An oxygen-containing pulse may include injecting a predefined concentration of the oxidizer (e.g. >150 g/Nm³ (gram per Normal cubic meter) into the processing chamber. The (e.g., gaseous) oxidizer (in some aspects referred to as oxidizing agent) may include or may be ozone (O₃), oxygen (O₂), water (H₂O), hydrogen peroxide (H₂O₂).

As detailed herein, the oxidation process may be adjusted to increase or decrease the oxygen concentration in the first sublayers and/or the second sublayers. Method 500 exemplary illustrates an adjustment of the oxidation process using atomic layer deposition (ALD). Here, the zirconium oxide may be formed by ALD using one or more first cycles each including a zirconium-containing precursor pulse and subsequently a first oxygen-containing precursor pulse with a first oxygen dose to form the zirconium oxide. The HZO may be formed by ALD using one or more second cycles each including: a hafnium-containing precursor pulse, a zirconium-containing precursor pulse, and subsequently at least one second oxygen-containing precursor pulse with a second oxygen dose to form (e.g., ferroelectric) hafnium zirconium oxide.

According to various aspects, the first oxygen dose may be substantially greater than the second oxygen dose. By this, the resulting first sublayers may have a first (average) oxygen concentration and the resulting second sublayers may have a second (average) oxygen concentration less than the first oxygen concentration (thus, u+v>0, e.g., u+v≥0.1, e.g., u+v≥0.2).

The oxygen dose may result from a combination of an oxygen concentration of the oxidizer itself (e.g., using ozone may have a higher oxygen concentration than using gaseous water), a concentration of the oxidizer within the atmosphere (e.g., the partial pressure thereof), and a pulse time (which may be, for example, in the range from about 1 second to about 30 seconds) for which the respective layer is exposed to the oxidizer.

In some aspects, the first oxygen-containing precursor pulse and the second oxygen-containing precursor pulse may use a same oxidizer. According to various aspects, first oxygen-containing precursor pulse and the second oxygen-containing precursor pulse may be ozone. In other aspects, the first oxygen-containing precursor pulse and the second oxygen-containing precursor pulse may use different oxidizers (e.g., one ozone and the other one water).

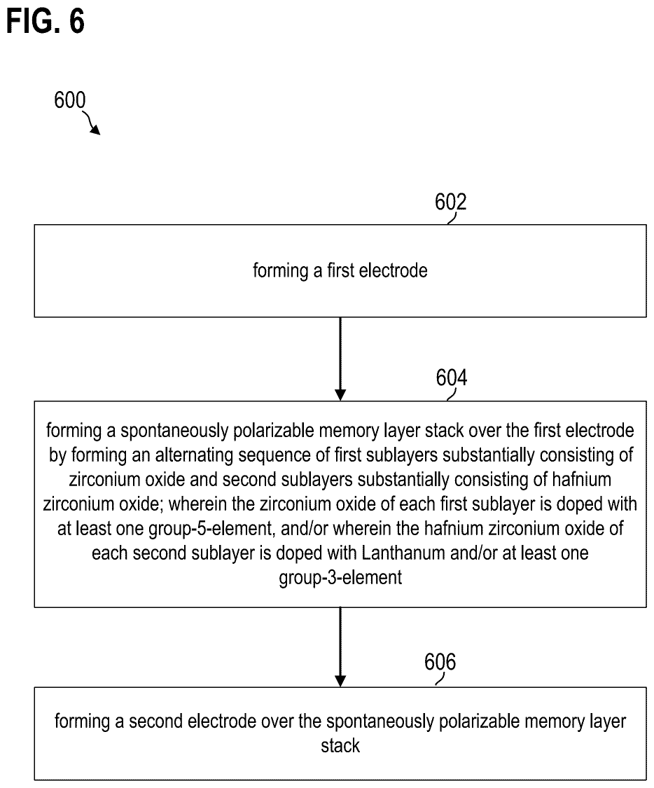

As detailed herein, the first sublayers may be doped to increase the first oxygen concentration and/or the second sublayers may be doped to decrease the second oxygen concentration. Each of the methods 400, 500, 600, 700 may include doping each of the first sublayers and/or each of the second sublayers A flow diagram of a method 600 of manufacturing a memory capacitor (e.g., including the SPOC structure 120) using doping of first and/or second sublayers is illustrated in FIG. 6. In this case, each first sublayer may substantially consist of doped zirconium oxide (e.g., doped with the first dopant β) and/or each second sublayer may substantially consist of doped HZO (e.g., doped with the second dopant a).

As detailed herein, the leakage may be reduced by using antiferroelectric hafnium oxide (instead of zirconium oxide). Hence, the memory capacitor may include a SPOC structure 120 as detailed with reference to FIG. 3G and FIG. 3H. Method 700 exemplary illustrates such a case. Thus, each first sublayer may substantially consist of antiferroelectric (doped) hafnium oxide and each second sublayer may substantially consist of HZO. As detailed herein, this configuration may be combined with the adjustment of the oxidation process and/or with the doping of the HZO. Optionally, the first sublayers and the second sublayers may be formed using atomic layer deposition (ALD). The antiferroelectric hafnium oxide may have the tetragonal crystal structure. The antiferroelectric hafnium oxide may be doped with the third dopant δ to stabilize the tetragonal crystal structure of hafnium oxide.

A spontaneously polarizable material, such as HZO may exhibit the spontaneously polarizable (e.g., ferroelectric) properties only in the crystalline phase. According to some aspects, the spontaneously polarizable material may be deposited already in the crystallized state. According to other aspects, the spontaneously polarizable material may be deposited substantially amorphous and crystallized afterwards. Hence, herein the material of the memory element 124 may be referred to as spontaneously polarizable material even in the amorphous state prior to exhibiting the spontaneously polarizable properties responsive to crystallization.

The spontaneously polarizable material (e.g., HZO) of the memory element 124 may be crystallized by annealing (e.g., thermally annealing). Each of the methods 400, 500, 600, 700 may optionally include an annealing of the spontaneously polarizable memory layer stack. The annealing may include a furnace annealing, a flash-lamp annealing, and/or a laser annealing. The annealing may be carried out in an inert gas atmosphere (e.g., nitrogen, e.g., argon) at any suitable pressure, e.g., at atmospheric pressure, at a pressure below atmospheric pressure, or at a pressure above atmospheric pressure. In some aspects, the annealing may be carried out in a vacuum. A vacuum in a processing chamber (e.g., for depositing a material and/or for annealing a material) may be provided in a pressure range below 50 mbar. For example, it may be possible to crystallize the HZO into the ferroelectric phase by annealing at temperatures in a range from about 300° C. to about 400° C. The crystallized spontaneously polarizable material may be polycrystalline including a plurality of crystallites and the crystallites may have the predefined crystallographic texture, as achieved by means of the amorphous functional layer(s). As an example, a majority of the crystallites (e.g., at least 50%, e.g., at least 75%, e.g., at least 90% of the crystallites) may be oriented along the same direction and therefore define a crystallographic texture. The term “texture”, as used herein, may describe a crystallographic texture as a property of a material or of a layer including a material. The crystallographic texture may be related to a distribution of crystallographic orientations of crystallites of a polycrystalline material. The crystallographic texture may be described by an orientation distribution function (ODF). A crystallographic texture of a layer, as referred to herein, may describe a preferred orientation of the crystallites of a polycrystalline material with reference to a surface of the layer. A crystallographic texture of a layer, as referred to herein, may describe a preferred orientation of the crystallites of a polycrystalline material with reference a direction of an external electric field caused by a voltage applied to electrodes contacting the layer. In other words, a material or layer consisting of crystallites may have no texture in the case that the orientations of the crystallites are randomly distributed. The material or layer may be regarded as a textured material or layer in the case that the orientations of the crystallites show one or more preferred directions. For example, a (001)-texture of the spontaneously polarizable memory layer may describe that most of the crystallites of the polycrystalline material that forms at least part of the spontaneously polarizable memory layer are oriented with their (001)-lattice planes along a direction perpendicular to the (e.g., upper) surface of the spontaneously polarizable memory layer. For example, a (001)-texture of the spontaneously polarizable material of the memory element 124 may describe that most of the crystallites of the polycrystalline material that forms at least part of the spontaneously polarizable material are oriented with their (001)-lattice planes along a direction perpendicular to a growth direction associated with the spontaneously polarizable material. As another example, a (111)-texture of the spontaneously polarizable material of the memory element 124 may describe that most of the crystallites of the polycrystalline material that forms at least part of the spontaneously polarizable material are oriented with their (111)-lattice planes along a direction perpendicular to the (e.g., upper) surface of the spontaneously polarizable material. For example, a (111)-texture of the spontaneously polarizable material may describe that most of the crystallites of the polycrystalline material that forms at least part of the spontaneously polarizable memory layer are oriented with their (111)-lattice planes along a direction perpendicular to a growth direction associated with the spontaneously polarizable memory layer. The (001)-texture may be a (001)-fiber-texture or a (001)-biaxial-texture. The (111)-texture may be a (111)-fiber-texture or a (111)-biaxial-texture. In general, the crystallographic texture may be described by the orientation distribution function (ODF), wherein x-ray diffraction patterns (e.g., pole-figure measurements, e.g., theta-2theta x-ray diffraction measurements with a scattering vector in plane-normal direction, such as perpendicular to a surface of electrodes of a planar capacitive memory structure) or other suitable measurements, e.g., based on transmission electron microscopy, electron backscatter diffraction (EBSD), or transmission Kikuchi diffraction (TKD), may be used to determine the orientation of the crystalline grains of the material.

In some aspects, the substrate may include or may be a silicon substrate e.g., with or without a (e.g., native) SiO₂ surface layer, or any other suitable semiconductor substrate. In other aspects, the substrate may include or may be an electrically non-conductive substrate, e.g., a glass substrate. In still other aspects, the substrate may include or may be an electrically conductive substrate, e.g., a metal substrate.

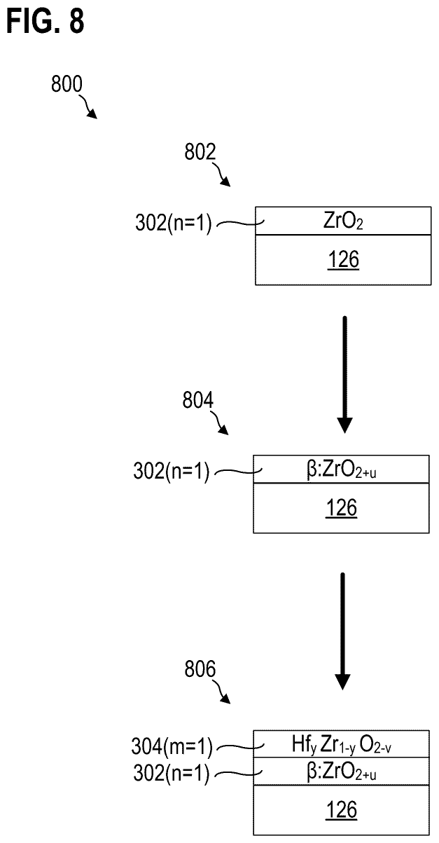

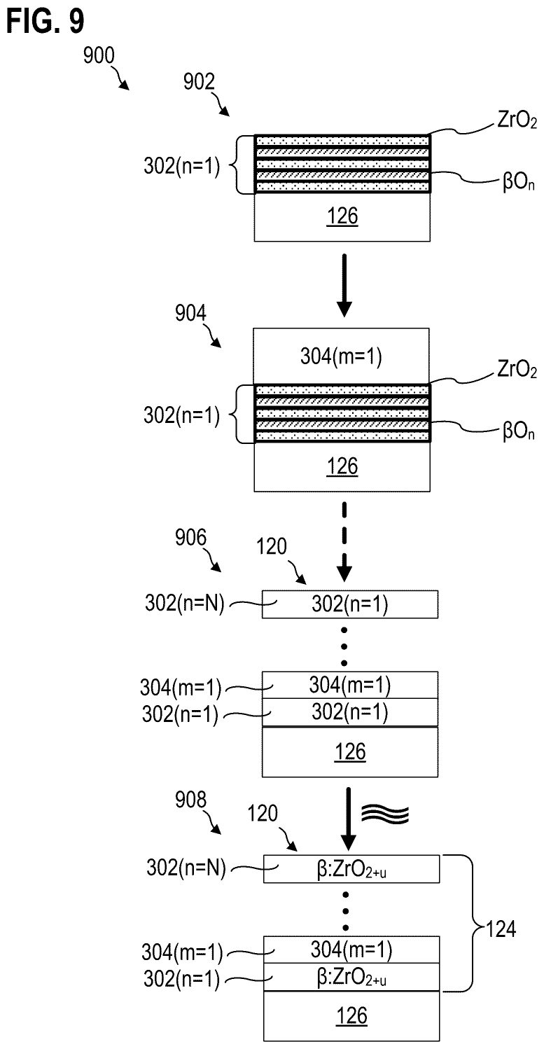

FIG. 8 and FIG. 9 each show exemplary configurations during forming a doped first sublayer of the memory capacitor according to various aspects. It is understood that this serves for illustration and that a second sublayer may be formed accordingly. Also, FIG. 8 and FIG. 9 exemplary illustrate a doping of zirconium oxide; it is understood that hafnium oxide may be doped accordingly.

With reference to FIG. 8, a first zirconium oxide layer of the spontaneously polarizable memory layer stack may be formed over the first electrode 126 (in 802). Although FIG. 8 shows the first zirconium oxide layer to be ZrO₂, it is understood that the first zirconium oxide layer may be formed to be over-stoichiometric as detailed herein.

Subsequently (in 804), the first zirconium oxide layer (i.e., a layer substantially consisting of zirconium oxide) may be doped with the first dopant β, thereby increasing the first oxygen concentration of the first zirconium oxide layer to form the first sublayer 302(n=1).

In 806, the second sublayer 304 (m=1) substantially consisting of (doped or undoped) HZO may be formed directly on the first sublayer 302(n=1). This may be repeated until the spontaneously polarizable memory layer stack is formed.

With reference to FIG. 9, forming the first sublayer 302(n=1) may include forming (in 902) a layer stack which includes at least one zirconium oxide layer (ZrO₂) and at least one layer containing the first dopant β (e.g., an oxide of the first dopant, such as niobium oxide).

Subsequently (in 904) the second sublayer 304 (m=1) substantially consisting of (doped or undoped) HZO may be formed directly on the layer stack. This may be repeated until the spontaneously polarizable memory layer stack is formed in 906.

The method may then (in 908) include annealing the spontaneously polarizable memory layer stack. This may intermix the layer stack to form the β-doped zirconium oxide.

As detailed herein, using a first oxygen dose (for forming each of the first sublayers) substantially greater than the second oxygen dose (for forming each of the second sublayers) may improve the electronic properties by improving the ferroelectric performance and/or by reducing leakage. This improvement may be even further increased when combining this oxygen dose variation with the doping disclosed herein. As detailed herein, the spontaneously polarizable memory layer stack may be annealed (in some aspects referred to as crystallization anneal) to exhibit the spontaneously polarizable properties of the spontaneously polarizable memory layer stack. During this annealing, oxygen diffusion within the spontaneously polarizable memory layer stack may take place. Doping the first sublayers with the first dopant β may allow the first sublayers to bind more oxygen atoms (than zirconium atoms), thereby stabilizing the higher first oxygen concentration in the first sublayers. Doping the second sublayers with the second dopant α may form as well as stabilize oxygen vacancies within the HZO, thereby stabilizing the lower second oxygen concentration in the second sublayers. Illustratively, doping the first and/or second sublayers may stabilize the oxygen concentration gradient in the spontaneously polarizable memory layer stack.

As detailed herein, each of the first and second sublayers may be formed over a three-dimensional structure using ALD. Using a first oxygen dose substantially greater than the second oxygen dose may result in a (low) oxygen gradient parallel to a surface of the substrate. Doping the first sublayers and/or the second sublayers (in addition or alternatively) may result in substantially no oxygen gradient along the surface of the substrate.

In the following, various examples are provided that may include one or more aspects described above with reference to a memory cell including the SPOC structure 120, to a memory cell arrangement including at least one such memory cell, and to the methods described herein. It may be intended that aspects described in relation to one or more of the methods may apply also to the memory cell and/or memory cell arrangement, and vice versa. For example, a method may include at least a part of the formation of the SPOC structure 120.

Example 1 is a memory cell including: a first electrode; a second electrode; and a memory element disposed between the first electrode and the second electrode, wherein the first electrode, the second electrode, and the memory element form a memory capacitor; wherein the memory element includes a spontaneously polarizable memory layer stack, the spontaneously polarizable memory layer stack including an alternating sequence of first sublayers and second sublayers, wherein each of the first sublayers substantially consists of zirconium oxide having a first (average) oxygen concentration, and wherein each of the second sublayers substantially consists of (ferroelectric) hafnium zirconium oxide having a second (average) oxygen concentration, wherein the first oxygen concentration is substantially greater than the second oxygen concentration.

In Example 2, the subject matter of Example 1 can optionally include that the first oxygen concentration is (in absolute terms) at least 1 at. % (e.g., 1 at. % or more than 1 at. %, such as 2 at. % or more than 2 at. %) greater than the second oxygen concentration.

In Example 3, the subject matter of Example 1 or 2 can optionally include that each first sublayer is over-stoichiometric regarding its oxygen concentration (e.g., ZrO₂₊ᵤ with u being greater than zero); and/or wherein each second sublayer is under-stoichiometric regarding its oxygen concentration (e.g., Hf_{y}Zr_{1-y} O₂₋ᵥ with v being greater than zero).

In Example 4, the subject matter of Example 3 can optionally include that each first sublayer is over-stoichiometric regarding its oxygen concentration by at least 5% (e.g., ZrO₂₊ᵤ with u≥0.1); and/or wherein each second sublayer is under-stoichiometric regarding its oxygen concentration by at least 5% (e.g., Hf_{y}Zr_{1-y} O₂₋ᵥ with v≥0.1).

In Example 5, the subject matter of any one of Examples 1 to 4 can optionally include that the first oxygen concentration is equal to or greater than about 67.7 at. % (e.g., ZrO_{w} with w being equal to or greater than about 2.1), preferably equal to or greater than about 68.7 at. % (e.g., ZrO_{w} with w being equal to or greater than about 2.2).

In Example 6, the subject matter of any one of Examples 1 to 5 can optionally include that the second oxygen concentration is equal to or less than about 65.5 at. % (e.g., Hf_{y}Zr_{1-y} Oz with z being equal to or less than about 1.9), preferably equal to or less than about 64.3 at. % (e.g., Hf_{y}Zr_{1-y} Oz with z being equal to or less than about 1.8).

In Example 7, the subject matter of any one of Examples 1 to 6 can optionally include that the zirconium oxide of each first sublayer is doped with at least one group-5-element.

In Example 8, the subject matter of Example 7 can optionally include that the at least one group-5-element includes one or more of: Niobium (Nb), Vanadium (V), Tantalum (Ta), and/or Dubnium (Db).

In Example 9, the subject matter of any one of Examples 1 to 8 can optionally include that each second sublayer is doped with Lanthanum (La) and/or at least one group-3-element.

In Example 10, the subject matter of Example 9 can optionally include that the at least one group-3-element includes one or more than one of: Scandium (Sc), Yttrium (Y), Lutetium (Lu), and/or Lawrencium (Lr).

Example 11 is a memory cell including: a first electrode; a second electrode; and a memory element disposed between the first electrode and the second electrode, wherein the first electrode, the second electrode, and the memory element form a memory capacitor; wherein the memory element includes a spontaneously polarizable memory layer stack, the spontaneously polarizable memory layer stack including an alternating sequence of first sublayers and second sublayers, wherein each of the first sublayers substantially consists of antiferroelectric hafnium oxide, and wherein each of the second sublayers substantially consists of (ferroelectric) hafnium zirconium oxide.

In Example 12, the subject matter of Example 11 can optionally include that the antiferroelectric hafnium oxide is doped with at least one dopant that stabilizes the tetragonal crystal structure of hafnium oxide.

In Example 13, the subject matter of Example 12 can optionally include that the least one dopant includes one or more of: Silicon (Si), Aluminum (Al), Lanthanum (La), Yttrium (Y), Niobium (Nb), and/or Gadolinium (Gd). Hence, a dopant (of the at least one dopant) may be Silicon (Si), Aluminum (Al), Lanthanum (La), Yttrium (Y), Niobium (Nb), or Gadolinium (Gd).

In Example 14, the subject matter of any one of Examples 1 to 13 can optionally include that the alternating sequence of the first sublayers and the second sublayers starts with one of the first sublayers and ends with another one of the first sublayers.

In Example 15, the subject matter of Example 14 can optionally include that the one of the first sublayers with which the alternating sequence starts and the other one of the first sublayers with which the alternating sequence ends have a same thickness.

In Example 16, the subject matter of any one of Examples 1 to 15 can optionally include that the spontaneously polarizable memory layer stack includes an odd number of second sublayers.

In Example 17, the subject matter of any one of Examples 1 to 16 can optionally include that the spontaneously polarizable memory layer stack is disposed in direct physical contact with the first electrode and the second electrode.

In Example 18, the subject matter of any one of Examples 1 to 17 can optionally include that each of the first sublayers has the same thickness; and/or wherein each of the second sublayers has the same thickness.

In Example 19, the subject matter of any one of Examples 1 to 18 can optionally include that each of the first sublayers has a respective thickness equal to or less than about 6 Å.

In Example 20, the subject matter of any one of Examples 1 to 19 can optionally include that each of the second sublayers has a respective thickness equal to or less than about 9 Å.

In Example 21, the subject matter of any one of Examples 1 to 20 can optionally include that at least part of the spontaneously polarizable memory layer stack is formed over a substrate portion having a three-dimensional structure.

In Example 22, the subject matter of Example 21 can optionally include that the three-dimensional structure has a width equal to or less than 200 nm and/or an aspect ratio equal to or greater than six (e.g., equal to or greater than ten, e.g., equal to or greater than fifteen, etc.).

In Example 23, the subject matter of Example 21 or 22 can optionally include that the spontaneously polarizable memory layer stack has substantially no oxygen gradient parallel to a surface of the substrate portion.

In Example 24, the subject matter of any one of Examples 1 to 23 can optionally include that the spontaneously polarizable memory layer stack is formed by atomic layer deposition (ALD).

Example 25 is a (e.g., FeRAM) memory cell arrangement including: a plurality of memory cells, wherein at least one (e.g., each) memory cell of the plurality of memory cells is configured in accordance with the memory cell of any one of Examples 1 to 24; and a plurality of sets of control lines for selectively addressing one or more memory cells of the plurality of memory cells.

Example 26 is a method of manufacturing a memory capacitor, the method including: forming a first electrode; forming a spontaneously polarizable memory layer stack over the first electrode layer by forming an alternating sequence of first sublayers and second sublayers, wherein each of the first sublayers substantially consists of zirconium oxide having a first (average) oxygen concentration, and wherein each of the second sublayers substantially consists of (ferroelectric) hafnium zirconium oxide having a second (average) oxygen concentration, wherein the first oxygen concentration is substantially greater than the second oxygen concentration; and forming a second electrode over the spontaneously polarizable memory layer stack.

Example 27 is a method of manufacturing a memory capacitor, the method including: forming a first electrode; forming a spontaneously polarizable memory layer stack over the first electrode layer by forming an alternating sequence of first sublayers and second sublayers; and forming a second electrode over the spontaneously polarizable memory layer stack; wherein forming a respective first sublayer of the first sublayers includes one or more first cycles of atomic layer deposition, wherein each of the one or more first cycles includes: a zirconium-containing precursor pulse and subsequently a first oxygen-containing precursor pulse with a first oxygen dose to form zirconium oxide; wherein forming a respective second sublayer of the second sublayers includes one or more second cycles of atomic layer deposition, wherein each of the one or more second cycles includes: a hafnium-containing precursor pulse, a zirconium-containing precursor pulse, and subsequently a second oxygen-containing precursor pulse with a second oxygen dose to form (ferroelectric) hafnium zirconium oxide; wherein the first oxygen dose is substantially greater than the second oxygen dose.

In Example 28, the subject matter of Example 27 can optionally include that each of the first sublayers is formed such that the zirconium oxide has a first (average) oxygen concentration; wherein each of the second sublayers is formed such that the hafnium zirconium oxide has a second (average) oxygen concentration; and wherein the first oxygen concentration is substantially greater than the second oxygen concentration.

In Example 29, the subject matter of Example 27 or 28 can optionally include that the first oxygen-containing precursor pulse and the second oxygen-containing precursor pulse include a same oxidizer; or wherein the first oxygen-containing precursor pulse and the second oxygen-containing precursor pulse include different oxidizers.

In Example 30, the subject matter of any one of Examples 27 to 29 can optionally include that the first oxygen-containing precursor pulse and the second oxygen-containing precursor pulse include one of the following (e.g., gaseous) oxidizers: ozone (O₃), oxygen (O₂), water (H₂O), hydrogen peroxide (H₂O₂). Thus, one of those precursor pulses may be used to form each of the first sublayers of Example 1. Illustratively, each of the first sublayers of Example 1 may be formed by atomic layer deposition using one of the following (e.g., gaseous) oxidizers: ozone (O₃), oxygen (O₂), water (H₂O), hydrogen peroxide (H₂O₂).

In Example 31, the subject matter of any one of Examples 26 to 30 can optionally include that forming the respective first sublayer further includes: doping the zirconium oxide with at least one group-5-element.

In Example 32, the subject matter of Example 31 can optionally include that the at least one group-5-element includes one or more of: Niobium (Nb), Vanadium (V), Tantalum (Ta), and/or Dubnium (Db).

In Example 33, the subject matter of any one of Examples 26 to 32 can optionally include that forming the respective second sublayer further includes: doping the hafnium zirconium oxide with Lanthanum (La) and/or at least one group-3-element.

In Example 34, the subject matter of Example 33 can optionally include that the at least one group-3-element includes one or more than one of: Scandium (Sc), Yttrium (Y), Lutetium (Lu), and/or Lawrencium (Lr).

Example 35 is a method of manufacturing a memory capacitor, the method including: forming a first electrode; forming a spontaneously polarizable memory layer stack over the first electrode layer by forming an alternating sequence of first sublayers substantially consisting of zirconium oxide and second sublayers substantially consisting of hafnium zirconium oxide; and forming a second electrode over the spontaneously polarizable memory layer stack; wherein the zirconium oxide of each first sublayer is doped with at least one group-5-element, and/or wherein the hafnium zirconium oxide of each second sublayer is doped with Lanthanum (La) and/or at least one group-3-element.

In Example 36, the subject matter of Example 35 can optionally include that the at least one group-5-element includes one or more of: Niobium (Nb), Vanadium (V), Tantalum (Ta), and/or Dubnium (Db).

In Example 37, the subject matter of Example 35 or 36 can optionally include that the at least one group-3-element includes one or more than one of: Scandium (Sc), Yttrium (Y), Lutetium (Lu), and/or Lawrencium (Lr).

In Example 38, the subject matter of any one of Examples 26 to 37 can optionally include that forming a respective first sublayer of the first sublayers includes: forming (e.g., using atomic layer deposition) a layer substantially consisting of zirconium oxide and doping the layer with the at least one group-5-element.

In Example 39, the subject matter of any one of Examples 26 to 37 can optionally include that forming a respective first sublayer of the first sublayers includes one or more first cycles of forming, using atomic layer deposition, a first layer substantially consisting of zirconium oxide, and includes at least one second cycle of forming, using atomic layer deposition, a second layer substantially consisting of an oxide of the at least one group-5-element.

In Example 40, the subject matter of any one of Examples 26 to 39 can optionally include that forming a respective second sublayer of the second sublayers includes: forming (e.g., using atomic layer deposition) a layer substantially consisting of hafnium zirconium oxide and doping the layer with the Lanthanum and/or the at least one group-3-element.

In Example 41, the subject matter of any one of Examples 26 to 39 can optionally include that forming a respective second sublayer of the second sublayers includes: one or more first cycles of forming, using atomic layer deposition, a first layer substantially consisting of zirconium oxide, one or more second cycles of forming, using atomic layer deposition, a second layer substantially consisting of hafnium oxide, and at least one third cycle of forming, using atomic layer deposition, a third layer substantially consisting of an oxide of the Lanthanum and/or the at least one group-3-element.

Example 42 is a method of manufacturing a memory capacitor, the method including: forming a first electrode; forming a spontaneously polarizable memory layer stack over the first electrode layer by forming an alternating sequence of first sublayers and second sublayers, wherein each of the first sublayers substantially consists of antiferroelectric hafnium oxide, and wherein each of the second sublayers substantially consists of (ferroelectric) hafnium zirconium oxide; and forming a second electrode over the spontaneously polarizable memory layer stack.

In Example 43, the subject matter of Example 42 can optionally include that the antiferroelectric hafnium oxide of each first sublayer is doped with at least one dopant that stabilizes the tetragonal crystal structure of hafnium oxide.

In Example 44, the subject matter of Example 42 or 43 can optionally include that forming a respective first sublayer of the first sublayers includes: forming a layer substantially consisting of hafnium oxide (e.g., using atomic layer deposition) and doping the layer with at least one dopant that stabilizes the tetragonal crystal structure of hafnium oxide.

In Example 45, the subject matter of Example 43 or 44 can optionally include that the least one dopant includes one or more of: Silicon (Si), Aluminum (Al), Lanthanum (La), Yttrium (Y), Niobium (Nb), and/or Gadolinium (Gd).

In Example 46, the subject matter of any one of Examples 26 to 45 can optionally include that forming the spontaneously polarizable memory layer stack includes forming at least part of the spontaneously polarizable memory layer stack over a substrate portion having a three-dimensional structure.

In Example 47, the subject matter of Example 46 can optionally include that the three-dimensional structure has a width equal to or less than 200 nm and/or an aspect ratio equal to or greater than six (e.g., equal to or greater than ten, e.g., equal to or greater than fifteen, etc.).

In Example 48, the subject matter of Example 46 or 47 can optionally include that the spontaneously polarizable memory layer stack has substantially no oxygen gradient parallel to a surface of the substrate portion.

In Example 49, the subject matter of any one of Examples 26 to 48 can optionally include that the spontaneously polarizable memory layer stack is formed by atomic layer deposition (ALD).

In Example 50, the method of any one of Examples 1 to 49 can optionally further include: annealing the spontaneously polarizable memory layer stack.

Example 51 is a method of manufacturing a (e.g., FeRAM) memory cell arrangement including: forming a plurality of memory cells in accordance with the method of any one of Examples 26 to 50; and forming a plurality of sets of control lines for selectively addressing one or more memory cells of the plurality of memory cells.

Several aspects are described with reference to a structure (e.g., a memory transistor structure, a field-effect transistor based memory structure, such as a ferroelectric field-effect transistor based memory structure, a capacitor-based memory structure (e.g., including one or more capacitors), such as a 1C (one capacitor) memory cell or a 1C1T (one capacitor and one transistor) memory cell (wherein the transistor in a 1C1T memory cell is an access transistor) and it is noted that such a structure may include solely the respective element (e.g., a memory transistor, a field-effect transistor, a ferroelectric field-effect transistor, a capacitive memory); or, in other aspects, a structure may include the respective element and one or more additional elements.

The term “switch” may be used herein to describe a modification of the memory state a memory cell is residing in. For example, in the case that a memory cell is residing in a first memory state (e.g., the LVT state), the memory state the memory cell is residing in may be switched such that, after the switch, the memory cell may reside in a second memory state (e.g., the HVT state), different from the first memory state. The term “switch” may thus be used herein to describe a modification of the memory state a memory cell is residing in, from a first memory state to a second memory state. The term “switch” may also be used herein to describe a modification of a polarization, for example of a spontaneously-polarizable memory element (e.g., of a spontaneously-polarizable layer, such as a remanent-polarizable layer). For example, a polarization of a spontaneously-polarizable memory element may be switched, such that the sign of the polarization varies from positive to negative or from negative to positive, while the absolute value of the polarization may remain in some aspects substantially unaltered. According to various aspects, writing a memory cell may include bringing the memory cell from one of at least two memory states into another one of the at least two memory states of the memory cell (e.g., from the LVT state into the HVT state, or vice versa).

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g., provided by a metal or degenerate semiconductor in absence of p-n junctions in the current path. The term “electrically conductively connected” may be also referred to as “galvanically connected”.

The term “coupled to” used herein with reference to functional parts of a memory cell (e.g., functional parts of a memory structure) that are coupled to respective nodes (e.g., source-line node, bit-line node, and/or word-line node) of the memory cell may be understood as follows: the respective functional parts are electrically conductively connected to corresponding nodes and/or the respective functional parts itself provide the corresponding nodes. As an example, a source/drain node of a field-effect transistor memory structure may be electrically conductively connected to the source-line node of the memory cell or the source/drain node of the field-effect transistor memory structure may provide the source-line node of the memory cell. As another example, a source/drain node of the field-effect transistor memory structure may be electrically conductively connected to the bit-line node of the memory cell or the source/drain node of the field-effect transistor memory structure may provide the bit-line node of the memory cell.

The term “voltage” may be used herein with respect to “one or more bitline voltages”, “one or more wordline voltages”, “one or more plateline voltages”, “one or more sourceline voltages”, “one or more control line voltages”, “one or more base voltages” and the like. As an example, the term “base voltage” may be used herein to denote a reference voltage and/or a reference potential for the circuit. With respect to an electrical circuit, the base voltage may be also referred to as ground voltage, ground potential, virtual ground voltage, or zero volts (0 V). The base voltage of an electrical circuit may be defined by the power supply used to operate the electronic circuit. As another example, the term “control line voltage” may be used herein to denote a voltage that is provided to a control line, e.g., of a memory cell arrangement (for example a “wordline voltage” may be provided to a “wordline”, a “bitline voltage” may be provided to a bitline, a “sourceline voltage” may be provided to a sourceline, and a “plateline voltage” may be provided to a plateline). The sign of a voltage difference (e.g., a voltage drop) may be defined as a potential inside a memory cell (e.g., at a first electrode portion) minus a potential at a second electrode portion of the memory cell.

In some aspects, two voltages may be compared with one another by relative terms such as “greater”, “higher”, “lower”, “less”, or “equal”, for example. It is understood that, in some aspects, a comparison may include the sign (positive or negative) of the voltage value or, in other aspects, the absolute voltage values (also referred to as the magnitude, or as the amplitude, e.g., of a voltage pulse) are considered for the comparison.

The phrase “a current between” a first terminal or node and a second terminal or node may be used herein to mean a current from the first terminal or node to the second terminal or node as well as a current from the second terminal or node to the first terminal or node.

The phrase “a current through” a terminal, node, or region may be used herein to mean a current from the terminal or node to another terminal, another node, or another region as well as a current to the terminal, node, or region (e.g., from another terminal, another node, or another region).

A current may be detected using a current sense amplifier that outputs a voltage proportional to the current.

The phrase that a layer “substantially consists of” a material, as used herein, may be understood to mean that the layer may include other materials; however, a concentration of the other materials may be significantly lower than a concentration of the material. That the layer “substantially consists of” the material may be understood to mean that the layer includes at least 90 at. % (e.g., at least 95 at. %, e.g., about 100 at. %) of the material or more (hence, the concentration of the material may be equal to or greater than 90 at. %). For example, a layer that substantially consists of hafnium oxide may consist of hafnium zirconium oxide, Hf_{y}Zr_{1-y}O₂, with 0.9≤y≤1. Thus, as used herein, a sublayer may substantially consist of a material (such as HZO) even when being doped with one or more other elements (e.g., the at least one second dopant a). It may be understood that even in the case that a layer substantially consists of a specific material (e.g., zirconium oxide (ZrO₂), one or more other materials may diffuse from a neighboring layer into the layer such that the layer may include a small number of atoms of the one or more other materials.

The phrase “substantially different”, as used herein, may be understood to mean that either the first concentration is substantially more than the second concentration or that the second concentration is substantially more than the first concentration. In the following, for illustrative purposes, the second concentration is described to be substantially more than the first concentration. However, it is understood that the first concentration may be substantially more than the second concentration in an analogous manner. The phrase that a second concentration of a second transition metal may be “substantially more” than a first concentration of a first transition metal (or vice versa) may be understood to mean that the second concentration of the second transition metal is at least 1.5-times the first concentration of the first transition metal. For example, the second concentration of the second transition metal may be at least twice the first concentration of the first transition metal. In an exemplary case that a layer includes hafnium zirconium oxide, Hf_{y}Zr_{1-y}O₂, the second concentration of the second transition metal, Hf, may be substantially more than the first concentration of the first transition metal, Zr, such that 0<x≤0.4. Hence, a concentration of the (second) oxide of the second transition metal (e.g., of HfO₂) may be equal to or greater than 60 at. % (e.g., equal to or greater than 55 at. %, e.g., equal to or greater than 70 at. %, e.g., equal to or greater than 75 at. %, etc.).

As used herein, a “concentration” of an element (e.g., of a transition metal) may refer to an atomic concentration (in at. %) of the element. Thus, in the case that the concentration of one element is compared to the concentration of another element, the atomic percentage of the one element may be compared to the atomic percentage of the other element. It is understood that a relation between the atomic percentage of the one element and the atomic percentage of the other element may directly refer to an atomic ratio between the one element and the other element. For example, in the case that the concentration (e.g., the atomic concentration) of the one element may be two times the concentration (e.g., the atomic concentration) of the other element, the atomic ratio between the one element and the other element may be 2 to 1 (2:1).

The term “metal” or “metal material” may be used herein to describe a metal (e.g., a pure or substantially pure metal) or a mixture of more than one metal, viz. a metal alloy. A “metal” may be an intermetallic material. Illustratively, the term “metal” may be used herein to describe a material having an electrical conductivity typical of a metal, for example an electrical conductivity greater than 106 S/m at a temperature of 20° C. The term “metal material” may be used herein to describe a material having the Fermi level inside at least one band. Therefore, in some aspects, the term “metal” may refer to a metalloid (also referred to as half-metal or semi-metal).

The terms “electrically conducting” or “electrically conductive” may be used herein interchangeably to describe a material or a layer having an electrical conductivity or an average electrical conductivity greater than 106 S/m at a temperature of 20° C. The term “electrically insulating” may be used herein interchangeably to describe a material or a layer having an electrical conductivity or an average electrical conductivity less than 10-10 S/m at a temperature of 20° C. In some aspects, a difference in electrical conductivity between an electrically conducting material (or layer) and an electrically insulating material (or layer) may have an absolute value of at least 10¹⁰ S/m at a temperature of 20° C., or of at least 1015 S/m at a temperature of 20° C.

The term “content” may be used herein, in some aspects, in relation to the “content of an element” in a material or in a layer to describe the mass percentage (or fraction) of that element over a total mass of the material (or of the layer). The term “content” may be used herein in relation to the “content of defects” in the structure of a material to describe the mass percentage of the defects over a total mass of the constituents of the structure. The term “content” may be used herein, in some aspects, in relation to the “content of an element” in a material or in a layer to describe the volume percentage of that element over a total volume of the material (or of the layer). The term “content” may be used herein in relation to the “content of defects” in the structure of a material to describe the volume percentage of the defects over a total volume of the structure.

The expression “a material of an element” or “a material of a layer”, for example “a material of a memory element”, or “a material of an electrode layer” may be used herein to describe a main component of that element or layer, e.g., a main material (for example, a main element or a main compound) present in that element or layer. The expression “a material of an element” or “a material of a layer” may describe, in some aspects, the material of that element or layer having a weight percentage greater than 60% over the total weight of the materials that the element or layer includes. The expression “a material of an element” or “a material of a layer” may describe, in some aspects, the material of that element or layer having a volume percentage greater than 60% over the total volume of the materials that the element or layer includes. As an example, a material of an element or layer including aluminum may describe that that element or layer is formed mostly by aluminum, and that other elements (e.g., impurities) may be present in a smaller proportion, e.g., having less weight percentage or less volume percentage compared to aluminum. As another example, a material of an element or layer including titanium nitride may describe that that element or layer is formed mostly by titanium nitride, and that other elements (e.g., impurities) may be present in a smaller proportion, e.g., having less weight percentage or less volume percentage compared to titanium nitride.

The term “region” used with regards to a “source region”, “drain region”, “channel region”, and the like, may be used herein to mean a continuous region of a semiconductor portion (e.g., of a semiconductor wafer or a part of a semiconductor wafer, a semiconductor layer, a fin, a semiconductor nanosheet, a semiconductor nanowire, etc.,). In some aspects, the continuous region of a semiconductor portion may be provided by semiconductor material having only one dominant doping type.

The word “over”, used herein to describe forming a feature, e.g., a layer “over” a side or surface, may be used to mean that the feature, e.g., the layer, may be formed “directly on”, e.g., in direct contact with, the implied side or surface. The word “over”, used herein to describe forming a feature, e.g., a layer “over” a side or surface, may be used to mean that the feature, e.g., the layer, may be formed “indirectly on” the implied side or surface with one or more additional layers being arranged between the implied side or surface and the formed layer.

The term “lateral” used with regards to a lateral dimension (in other words a lateral extent) of a structure, a portion, a structure element, a layer, etc., provided, for example, over and/or in a carrier (e.g., a layer, a substrate, a wafer, etc.) or “laterally” next to, may be used herein to mean an extent or a positional relationship along a surface of the carrier. That means, in some aspects, that a surface of a carrier (e.g., a surface of a layer, a surface of a substrate, a surface of a wafer, etc.) may serve as reference, commonly referred to as the main processing surface. Further, the term “width” used with regards to a “width” of a structure, a portion, a structure element, a layer, etc., may be used herein to mean the lateral dimension (or in other words the lateral extent) of a structure. Further, the term “height” used with regards to a height of a structure, a portion, a structure element, a layer, etc., may be used herein to mean a dimension (in other words an extent) of a structure in a direction perpendicular to the surface of a carrier (e.g., perpendicular to the main processing surface of a carrier).

The term “thickness” used with regards to a “thickness” of a layer may be used herein to mean the dimension (in other words an extent) of the layer perpendicular to the surface of the support (the material or material structure) on which the layer is formed (e.g., deposited or grown). If a surface of the support is parallel to the surface of the carrier (e.g., parallel to the main processing surface) the “thickness” of the layer formed on the surface of the support may be the same as the height of the layer.

According to various aspects, various properties (e.g., physical properties, chemical properties, etc.) of a first component (e.g., elements, layers, structures, portions, etc.) and a second component may be compared to one another. It may be found that two or more components may be—with reference to a specific property-either equal to each other or different from one another. As a measure, a value that represents such a property may be either equal or not. In general, a skilled person may understand from the context of the application whether two values or properties are equal or not, e.g., usually, if values are in the range of a usual tolerance, they may be regarded equal. However, in some aspects or as long as not otherwise mentioned or understood, two values that differ from one another with at least 1% relative difference may be considered different from one another. Accordingly, two values that differ from one another with less than 1% relative difference may be considered equal to each other.

It may be understood, that the physical term “electrical conductivity” (also referred to as specific conductance, specific electrical conductance, as examples) may be defined as a material dependent property reciprocal to the physical term “electrical resistivity” (also referred to as specific electrical resistance, volume resistivity, as examples). Further properties of a layer or structure may be defined material dependent and the geometry dependent, e.g., by the physical terms “electrical resistance” and “electrical conductance”.

According to various aspects, the properties and/or the structure of the memory element, an electrode, an electrically conductive electrode layer, and/or a functional layer as described herein may be evaluated with techniques known in the art. As an example, transmission electron microscopy (TEM) may be used to determine the structure of an electrode, for example the presence of one or more electrode layers and/or the presence of one or more functional layers in the electrode. TEM may be used for identifying a layer, an interface, a crystal structure, a microstructure, and other properties. As another example, X-ray crystallography (X-ray diffraction) may be used to determine various properties of a layer or a material, such as the crystal structure, the lattice properties, the size and shape of a unit cell, the chemical composition, the phase or alteration of the phase, the presence of stress in the crystal structure, the microstructure, and the like. As a further example, energy-dispersive X-ray spectroscopy (EDS) and/or hard x-ray photoelectron spectroscopy (HAXPES) may be used to determine the chemical composition of a layer or a material, e.g. the presence and/or the content of an element in the layer or material. As a further example, Rutherford backscattering spectrometry (RBS) may be used to determine the structure and/or the composition of a material. As a further example, secondary ion mass spectrometry (SIMS) may be used to analyze the molecular composition of the upper monolayers of a solid, e.g. for analyzing the spatial distribution (e.g., the gradient) of an element across the solid.

A composition of a layer, a concentration of one or more materials within the layer, a composition of a layer, and/or a concentration of one or more materials within the spontaneously polarizable memory element, etc. may be determined with techniques known in the art. For example, energy-dispersive X-ray spectroscopy (EDS) (e.g., in combination with scanning electron microcopy (SEM) or transmission electron microscopy (TEM)), Rutherford backscattering spectrometry (RBS), and/or secondary ion mass spectrometry (SIMS) may be used to analyze the composition and/or concentration. However, the composition of the layer, the concentration of the one or more materials within the layer, the composition of the spontaneously polarizable memory element, and/or the concentration of the one or more materials within the spontaneously polarizable memory element may be also apparent from a manufacturing protocol for manufacturing the respective layer. For example, a layer may be manufactured by means of deposition, such as atomic layer deposition (ALD) and the respective composition and/or concentration may be directly apparent from the used deposition protocol (e.g., the used ALD deposition protocol).

The terms “at least one” and “one or more” may be understood to include any integer number greater than or equal to one, i.e. one, two, three, four, [ . . . ], etc. The term “a plurality” or “a multiplicity” may be understood to include any integer number greater than or equal to two, i.e. two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The phrase that an element or a group of elements “includes” another element or another group of elements may be used herein to mean that the other element or other group of elements may be part of the element or the group of elements or that the element or the group of elements may be configured or formed as the other element or the other group of elements (e.g., the element may be the other element).

The phrase “unambiguously assigned” may be used herein to mean a one-to-one-assignment (e.g., allocation, e.g., correspondence) or a bijective assignment. As an example, a first element being unambiguously assigned to a second element may include that the second element is unambiguously assigned to the first element. As another example, a first group of elements being unambiguously assigned to a second group of element may include that each element of the first group of elements is unambiguously assigned to a corresponding element of the second group of elements and that that corresponding element of the second group of elements is unambiguously assigned to the element of the first group of elements.

An “electrically conductive” connection or coupling, as described herein, may include a direct electrical connection or an indirect electrical connection, wherein an indirect connection may include additional structures in the current path that have no influence on the substantial functioning of the described circuit or device.

A group-x-element (e.g., a group-5-element or a group-3-element) as used herein may refer to the corresponding group, x, of the periodic table.

It is noted that one or more functions described herein with reference to a memory cell, a memory cell arrangement, etc., may be accordingly part of a method, e.g., part of a method for operating a memory cell arrangement. Vice versa, one or more functions described herein with reference to a method, e.g., with reference to a method for operating a memory cell arrangement, may be implemented accordingly in a device or in a part of a device, for example, in a memory cell, a memory cell arrangement, etc.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A memory cell, comprising:
a first electrode;
a second electrode; and
a memory element disposed between the first electrode and the second electrode, wherein the first electrode, the second electrode, and the memory element form a memory capacitor;
wherein the memory element comprises a spontaneously polarizable memory layer stack, the spontaneously polarizable memory layer stack comprising an alternating sequence of first sublayers and second sublayers, wherein each of the first sublayers substantially consists of zirconium oxide having a first oxygen concentration, and wherein each of the second sublayers substantially consists of hafnium zirconium oxide having a second oxygen concentration, wherein the first oxygen concentration is substantially greater than the second oxygen concentration.

2. The memory cell according to claim 1,
wherein the first oxygen concentration is at least 1 at. % greater than the second oxygen concentration.

3. The memory cell according to claim 1,
wherein each first sublayer is over-stoichiometric regarding its oxygen concentration; and/or
wherein each second sublayer is under-stoichiometric regarding its oxygen concentration.

4. The memory cell according to claim 1,
wherein the first oxygen concentration is equal to or greater than about 67.7 at. %; and/or
wherein the second oxygen concentration is equal to or less than about 65.5 at. %.

5. The memory cell according to claim 1,
wherein the zirconium oxide of each first sublayer is doped with at least one group-5-element.

6. The memory cell according to claim 5,
wherein the at least one group-5-element comprises Niobium.

7. The memory cell according to claim 1,
wherein each second sublayer is doped with Lanthanum and/or at least one group-3-element.

8. The memory cell according to claim 1,
wherein the alternating sequence of the first sublayers and the second sublayers starts with one of the first sublayers and ends with another one of the first sublayers; and
wherein the spontaneously polarizable memory layer stack is disposed in direct physical contact with the first electrode and the second electrode.

9. The memory cell according to claim 1,
wherein at least part of the spontaneously polarizable memory layer stack is formed over a substrate portion having a three-dimensional structure; and
wherein the spontaneously polarizable memory layer stack has substantially no oxygen gradient parallel to a surface of the substrate portion.

10. The memory cell according to claim 1,
wherein the spontaneously polarizable memory layer stack is formed by atomic layer deposition.

11. A memory cell, comprising:
a first electrode;
a second electrode; and
a memory element disposed between the first electrode and the second electrode, wherein the first electrode, the second electrode, and the memory element form a memory capacitor;
wherein the memory element comprises a spontaneously polarizable memory layer stack, the spontaneously polarizable memory layer stack comprising an alternating sequence of first sublayers and second sublayers, wherein each of the first sublayers substantially consists of antiferroelectric hafnium oxide, and wherein each of the second sublayers substantially consists of hafnium zirconium oxide.

12. The memory cell according to claim 11,
wherein the antiferroelectric hafnium oxide is doped with at least one dopant that stabilizes the tetragonal crystal structure of hafnium oxide.

13. The memory cell according to claim 12,
wherein the least one dopant comprises one or more of: Silicon, Aluminum, and/or Niobium.

14. A method of manufacturing a memory capacitor, the method comprising:
forming a first electrode;
forming a spontaneously polarizable memory layer stack over the first electrode layer by forming an alternating sequence of first sublayers and second sublayers; and
forming a second electrode over the spontaneously polarizable memory layer stack;
wherein forming a respective first sublayer of the first sublayers comprises one or more first cycles of atomic layer deposition, wherein each of the one or more first cycles comprises: a zirconium-containing precursor pulse and subsequently a first oxygen-containing precursor pulse with a first oxygen dose to form zirconium oxide;
wherein forming a respective second sublayer of the second sublayers comprises one or more second cycles of atomic layer deposition, wherein each of the one or more second cycles comprises: a hafnium-containing precursor pulse, a zirconium-containing precursor pulse, and subsequently a second oxygen-containing precursor pulse with a second oxygen dose to form hafnium zirconium oxide;
wherein the first oxygen dose is substantially greater than the second oxygen dose.

15. The method according to claim 14,
wherein each of the first sublayers is formed such that the zirconium oxide has a first oxygen concentration;
wherein each of the second sublayers is formed such that the hafnium zirconium oxide has a second oxygen concentration; and
wherein the first oxygen concentration is substantially greater than the second oxygen concentration.

16. The method according to claim 14,
wherein the first oxygen-containing precursor pulse and the second oxygen-containing precursor pulse comprise a same oxidizer; or
wherein the first oxygen-containing precursor pulse and the second oxygen-containing precursor pulse comprise different oxidizers.

17. The method according to claim 14,
wherein the first oxygen-containing precursor pulse and the second oxygen-containing precursor pulse comprise one of the following oxidizers: ozone, oxygen, water, hydrogen peroxide.

18. The method according to claim 14,
wherein forming the respective first sublayer of the first sublayers comprises: forming, using atomic layer deposition, a layer substantially consisting of zirconium oxide and doping the layer with at least one group-5-element.

19. The method according to claim 14,
wherein forming a respective first sublayer of the first sublayers comprises one or more first cycles of forming, using atomic layer deposition, a first layer substantially consisting of zirconium oxide, and comprises at least one second cycle of forming, using atomic layer deposition, a second layer substantially consisting of an oxide of the at least one group-5-element;
wherein the method further comprises annealing the spontaneously polarizable memory layer stack.

20. The method according to claim 14,
wherein forming the respective second sublayer further comprises: doping the hafnium zirconium oxide with Lanthanum and/or at least one group-3-element.
